(19) United States
(12) Patent Application Publication
(10) Pub. No.: US 2026/0159741 A1
(43) Pub. Date: Jun. 11, 2026

(54) Fused Filament Fabrication of a Thermally Conductive Dielectric Polymer Composite

(71) Applicants: Northeastern University, Boston, MA (US); U.S. Army Research Laboratory, Aberdeen Proving Ground, MD (US)

(72) Inventors: Randall Morgan ERB, Newton, MA (US); Daniel J. BRACONNIER, Boston, MA (US); Eric Dean WETZEL, Bel Air, MD (US); Ryan DUNN, Boston, MA (US); Evan Zachary TOTH, North Kingstown, RI (US)

(21) Appl. No.: 18/977,552

(22) Filed: Dec. 11, 2024

Related U.S. Application Data
(60) Provisional application No. 63/608,597, filed on Dec. 11, 2023.

(51) Int. Cl. C09K 5/14; B29C 64/118; B29C 64/314; B29K 67/00; B29K 105/18; B29K 509/04; B29L 31/34; B33Y 10/00; B33Y 40/10; B33Y 70/10; B33Y 80/00; C08K 3/38; C08K 9/06; C09D 7/40; C09D 7/62; C09D 167/04; H05K 7/20

(52) U.S. Cl. CPC C09K 5/14; B29C 64/118; B29C 64/314; B33Y 10/00; B33Y 40/10; B33Y 70/10; B33Y 80/00; C09D 7/62; C09D 7/70; C09D 167/04; H05K 7/2039; B29K 2067/046; B29K 2105/18; B29K 2509/04; B29K 2995/0007; B29K 2995/0013; B29K 2995/0027; B29L 2031/3406; C08K 2003/385; C08K 9/06; C08K 2201/001

(57) ABSTRACT

Non-metallic polymer composite materials with high thermal conductivity comparable to that of metals are provided. The materials are electrically insulative, RF transparent, and can be processed using widely accessible additive manufacturing systems. Polymeric crystallites are grown from surface-modified ceramic crystals to create hetero-percolated crystalline domains that dramatically enhance phononic transport and, thus, thermal conductivity. The new materials can be used across a wide range of electronic devices, from smart phones to phased array antennas, and remove constraints in developing electronic devices with higher power and smaller form factors.

### CROSS REFERENCE TO RELATED APPLICATIONS

This application claims the priority of U.S. Provisional Application No. 63/608,597 filed 11 Dec. 2023, the whole of which is hereby incorporated by reference.

### STATEMENT REGARDING FEDERALLY SPONSORED RESEARCH OR DEVELOPMENT

This invention was made with government support under Grant Numbers W911 NF-20-2-0024 and W911 NF-22-2-0261 awarded by the U.S. Army Research Office. The Government has certain rights in the invention.

### BACKGROUND

The predominant share of thermal management solutions is derived from sheet and machined metals due to the materials' intrinsic high thermal conductivity and manufacturing flexibility. However, the thermal conductivity of metal is married to electron mobility, which leads to an electrical conductivity that can prohibit the use of metals in certain electronic and telecommunication applications. Further, the high density of metals penalizes their use in fields that value lightweight solutions. Therefore, a lightweight and dielectric thermal management materials solution is desirable. Certain dielectric ceramics, known as phononic conductors, can effectively transport heat through atomic vibrations without electron movement. Due to the manufacturing complexities associated with these ceramics, recent interest in filling thermoplastic polymers with these phononic conductors has grown.

Thermal management materials and solutions are a current bottleneck in the realization of next generation high density electronic devices [1-5]. In fact, the existing field solution to prevent overheating of many of these devices (including smart phones and phased array antennas) consists of powering the device down or throttling the computation rates, both which significantly limit systems-level performance [1, 2, 6-8]. Creative thermal management solutions are being developed for these devices that include intricate through-board thermal vias, new thermal interface materials, and active cooling devices [9-12]. Many of these thermal solutions are based on metals due to the materials' high thermal conductivity and widely established processability. Metals present an electronic challenge however, in that this material's high thermal conductivity is married to high electrical conductivity. This fact creates a need to add additional electric barrier materials in the thermal path between the electrical device and the thermal management solution. Any additional bridging material introduces undue thermally resistant interfaces and lowers overall thermal conductivity. As such, there is a desire for new thermal management solutions that are both dielectric and thermally conductive, which would allow them to serve as a direct thermal bridge between the active electronic and cooling devices or, even better, allow them to serve directly as a combined thermal bridge and cooling device. That latter option would remove material interfaces, and the respective thermal resistances, and potentially increase the efficacy of thermal management solutions. Such a combination of devices and functionality requires the successful manufacturing of complex part geometries that can make intimate contact with active hot electronics and effectively transfer heat.

Additive manufacturing has provided significant opportunity for the manufacturing of complex part geometries for thermal management solutions. Many metal-based additive modalities have resoundingly demonstrated the benefit of additive-only geometries in the creation of heat exchangers and heat sinks [13-17]. Significantly less attention has been given to dielectric materials. Still, several research groups and even industrial companies have investigated the use of dielectric and thermally conductive fillers in polymeric carriers known as thermally conductive polymer composites (TCPCs) [18-21]. Dielectric filler particles like alumina and hexagonal boron nitride have been investigated due to their good thermal conductivities [22, 23]. Hexagonal boron nitride (hBN) is a phononic ceramic with a platelet morphology that exhibits ˜400 W/m·K thermal conductivity along the basal planes of its long axes (strong axis) and ˜30 W/m·K in its through-thickness (weak axis) direction. Since hBN is anisotropic, controlling the alignment and percolation along the basal planes of these platelets is imperative to maximize the key trait of high thermal conductivity.

In TCPC materials, the polymeric carrier creates a thermal resistance that can be combatted by increasing the volume fraction of the filler particles toward a percolation threshold [24, 25]. Unfortunately, increasing volume fraction toward the percolation threshold also causes the viscosity of these polymeric systems to spike, complicating the additive process [26-30]. This is true both in filled photoresin systems for stereolithographic printing as well as in filled thermoplastic systems for fused filament fabrication (FFF). Of these, FFF is an economic and prevalent form of additive manufacturing [31-35]. FFF processable TCPCs have achieved thermal conductivities up to ˜4 W/mK [18, 36], a relatively low value that is likely a result of prioritizing printability of the composite so that it can be easily processed without modifications to an existing FFF system. These lower conductivities are applicable for creating thermal management devices that move heat in lower heat flux electronic systems like LED lighting, microcontrollers, and battery array encapsulants [19-21, 37-39]. However, the creation of microstructural and morphological heterogeneities from the interaction between the complex flow within the extrusion process with the thermally conductive filler remains a technical challenge in making thermoplastic FFF parts [20, 36, 40, 41].

### SUMMARY

The present invention provides thermally conductive polymer dielectric composites containing phonon-conducting ceramics and methods for making them using fused filament fabrication. The materials are printable by additive manufacturing, have low-loss (i.e., are highly transparent to radio frequency electromagnetic radiation), and achieve thermal transmission at over 16 W/m·K, comparable to stainless steel.

Printable filament material can be made with application of thermal post-processing, which promotes templated crystallization in a polymer matrix from surface-modified boron nitride platelets, thereby creating a “hetero-percolated network”. The resulting material can be 3D-printed into heatsinks that perform as effectively as metal counterparts while being electrically insulative and RF transparent.

A multiscale approach was used to develop higher thermal conductivities through the compositional and microstructural design of FFF-printed TCPC parts. Consideration was given to macroscopic part and print orientation, microscopic print bead interfaces, nanoscopic particle surface chemistry, and polymer conformation. In an embodiment, the compositional and microstructural design process resulted in a semicrystalline poly-lactic acid (PLA) based TCPC filament compatible with conventional FFF printers that achieves an outstanding thermal conductivity of over 16 W/m·K. This thermal conductivity was enabled by thermal post-processing, which heals printed interfaces and drives templated crystallization in the PLA matrix from surface-modified boron nitride platelets. The crystalline domains percolate to form phononic bridges between the boron nitride platelets, a phenomenon referred to herein as “hetero-percolation”. Further, for common electronic and radiofrequency device applications, it was demonstrated that the present thermal management material can be used to produce heatsinks that cool as effectively as their heavier metal counterparts currently in use in industry.

An aspect of the invention is a thermally conductive dielectric polymer composite filament material suitable for use in 3D printing. The thermally conductive polymer composite (TCPC) material includes (i) a semi-crystalline polymeric material and (ii) a plurality of thermally conductive particles embedded in the polymeric material. The TCPC material preferably contains crystallites of the polymer material that form connections between the thermally conductive particles. The TCPC material preferably has a thermal conductivity of at least 15 W/m·K.

Another aspect of the invention is an electronic device containing the TCPC material described above.

Yet another aspect of the invention is a thermal management structure for an electronic device, the thermal management structure containing the TCPC material described above. A thermal management structure is any three-dimensional structure that functions to move heat energy into or out of a nearby object.

Still another aspect of the invention is a method of making the thermally conductive dielectric polymer composite filament material described above. The method includes the following steps: (a) providing a polymer material and a plurality of thermally conductive particles; (b) heating the polymer material to prepare a polymer melt; (c) mixing the plurality of thermally conductive particles with the polymer melt; and (d) forming the mixture from (c) into a desired shape and allowing the formed mixture to cool to form the TCPC material. In embodiments of the method, the method further includes: (e1) annealing the TCPC material by heating the material to a temperature below a melting temperature of the TCPC material for a period of time, whereby one or more properties of the material are altered. In certain embodiments of the method, the method includes: (e2) slow-cooling the TCPC from a temperature above Tc and Tg and below Tm down to about ambient temperature, whereby crystallite growth within the TCPC is promoted.

Yet another aspect of the invention is a TCPC material made by the method described above.

A further aspect of the invention is a method of designing or optimizing a process for producing a TCPC material suitable for use as a filament in a fused filament fabrication (FFF) process. The method includes the steps of: (a) selecting a polymer material having a melting point and a viscosity suitable for said FFF process; (b) selecting one or more thermally conductive particles for use as inclusions in the polymer material, wherein the one or more particle materials have a particle size distribution comprising particles having a size in a nanometer range and particles having a size in a micrometer range; (c) extruding a mixture of the polymer material of (a) and the thermally conductive particles of (b) to form a filament of a candidate TCPC material; (d) analyzing the filament according to one or more parameters selected from melting temperature of the filament, viscosity of a melt of the filament, suitability of the filament for use in an FFF process, thermal conductivity of the filament, dielectric properties of the filament, resilience of the filament, and spoolability of the filament; and (e) based on the analyzing of (d), revising the polymer material selection of (a) and/or the thermally conductive particle selection of (b) and repeating steps (c) and (d) with the revised selection(s) until one or more of said parameters is within a desired range for the TCPC material.

Still another aspect of the invention is a three dimensional object resulting from the deposition of a heated filament, the filament containing the TCPC material described above.

Even another aspect of the invention is a three-dimensional printing process including the steps of: (a) heating a filament comprising the TCPC material described above; (b) extruding the filament from a nozzle; (c) depositing the extruded filament to form a three-dimensional body, wherein the body has a geometry that is substantially identical to a digital design file that is used to program the three dimensional printing process.

The invention can be further summarized in the following list of features.
1. A thermally conductive polymer composite (TCPC) material comprising
   (i) a semi-crystalline polymeric material; and
   (ii) a plurality of thermally conductive particles embedded in the polymeric material;
   wherein the TCPC material comprises crystallites of the polymer material that form connections between the thermally conductive particles, or wherein the TCPC material has a thermal conductivity of at least 15 W/m·K.
2. The TCPC material of claim 1, wherein the plurality of thermally conductive particles comprise hexagonal boron nitride (hBN) platelets.
3. The TCPC material of claim 2, wherein the hBN platelets comprise hBN platelets having a size in a nanometer range and hBN platelets having a size in a micrometer range.
4. The TCPC material of claim 3, wherein the hBN platelets are present in a concentration range of 1 to 10 vol % in the nanometer range and 30 to 60 vol % in the micrometer range.
5. The TCPC material of any of the preceding claims, wherein at least 50% of the thermally conductive particles are in contact with one or more of said crystallites.
6. The TCPC material of any of the preceding claims, wherein the thermally conductive particles have a planar structure and are predominantly aligned in the TCPC material with the planar structures in a parallel configuration.
7. The TCPC material of any of the preceding claims, wherein the polymeric material is a thermoplastic material containing crystallites.
8. The TCPC material of any of the preceding claims, wherein the thermally conductive particles have been surface treated using a method selected from the group consisting of plasma treatment, solvent etching, metallization via evaporation, metallization via sputtering, UV-ozone, diamond coating, diamond-like coating, graphene coating, and graphitic coating.
9. The TCPC material of any of the preceding claims, wherein the polymer material comprises at least 10% or at least 30% volume fraction in form of crystallites.
10. The TCPC material of any of the preceding claims, wherein the polymer material comprises one or more of polyethylene (PE), low density PE (LDPE), high density PE (HDPE), ultra high molecular weight PE (UHMW PE), polyamide (PA), poly-para-phenylene terephthalamide (Kevlar), poly(meta phenyleneisophthalamide), polyetheretherketone (PEEK), polyoxymethylene, polyethylene terephthalate (PET), polybutylene terephthalate (PBT), polytetrafluoroethylene (PTFE), polypropylene (PP), isotactic PP, syndiotactic polystyrene (PS), polyphenylene sulfide (PPS), fluorinated ethylene propylene (FEP), polyvinylidene fluoride (PVDF), polylactic acid (PLA), and acrylonitrile butadiene styrene (ABS).
11. The TCPC material of any of the preceding claims, wherein the plurality of thermally conductive particles comprises particles having chemically derivatized surfaces.
12. The TCPC material of claim 11, wherein the chemical derivatization comprises hydroxylation or silanization of the particles.
13. The TCPC material of any of the preceding claims, wherein the TCPC material is electrically insulating and transparent to radio frequency electromagnetic radiation.
14. The TCPC material of any of the preceding claims, wherein the TCPC material is configured as a filament suitable for use in a fused filament fabrication (FFF) process.
15. The TCPC material of claim 14, wherein the filament has a resilience of at least about 0.2 J/m³ and can be wrapped tightly around a spool of diameter 200 mm or less without filament breakage.
16. A thermal management structure for an electronic device, the thermal management structure comprising the TCPC material according to any of claims 1-15.
17. The thermal management structure of claim 16, wherein the structure is made by a process comprising 3D printing, injection molding, compression molding, or machining.
18. An electronic device comprising the TCPC material of any of claims 1-15.
19. A method of making a TCPC material, the method comprising
   (a) providing a polymer material and a plurality of thermally conductive particles;
   (b) heating the polymer material to prepare a polymer melt;
   (c) mixing the plurality of thermally conductive particles with the polymer melt; and
   (d) forming the mixture from (c) into a desired shape and allowing the formed mixture to cool to form the TCPC material.
20. The method of claim 19, further comprising
   (e1) annealing the TCPC material by heating the material to a temperature below a melting temperature of the TCPC material for a period of time, whereby one or more properties of the material are altered.
21. The method of claim 19 or claim 20, further comprising
   (e2) slow-cooling the TCPC from a temperature above Tc and Tg and below Tm down to about ambient temperature, whereby crystallite growth within the TCPC is promoted.
22. The method of any of claims 19-21, wherein one or more process additives are added to the mixture formed in step (c), wherein the process additives are selected from the group consisting of solvents, plasticizers, surfactants, dispensing aids, antioxidants, stabilizers, and colorants.
23. The method of any of claims 19-22, wherein any of steps (b)-(d) is performed using an extruder device.
24. The method of any of claims 19-23, wherein the thermally conductive particles are hBN platelets, wherein the polymer material comprises one or more of polyethylene (PE), low density PE (LDPE), high density PE (HDPE), ultra high molecular weight PE (UHMW PE), polyamide (PA), poly-para-phenylene terephthalamide (Kevlar), poly(meta phenyleneisophthalamide), polyetheretherketone (PEEK), polyoxymethylene, polyethylene terephthalate (PET), polybutylene terephthalate (PBT), polytetrafluoroethylene (PTFE), polypropylene (PP), isotactic PP, syndiotactic polystyrene (PS), polyphenylene sulfide (PPS), fluorinated ethylene propylene (FEP), polyvinylidene fluoride (PVDF), polylactic acid (PLA), and acrylonitrile butadiene styrene (ABS), and wherein the hBN platelets comprise hBN platelets having a size in a nanometer range and hBN platelets having a size in a micrometer range.
25. A method of making a thermal dissipation structure, the method comprising forming the TCPC material of any of claims 1-15 into a structure for use as a thermal dissipation structure.
26. The method of claim 25, wherein the thermal dissipation structure serves as, or is incorporated into, a device selected from the group consisting of a thermal management device, a heat sink or a heat spreader, a heat exchanger, a radiator, a cold plate, a low-loss dielectric RF component, a power inverter, a solar cell, a neutron shield, an encapsulant, an antenna, or a medical device.
27. A TCPC material made by the method of any of claims 19-24.
28. A method of designing or optimizing a process for producing a TCPC material suitable for use as a filament in a fused filament fabrication (FFF) process, the method comprising the steps of
   (a) selecting a polymer material having a melting point and a viscosity suitable for said FFF process;
   (b) selecting one or more thermally conductive particles for use as inclusions in the polymer material, wherein the one or more particle materials have a particle size distribution comprising particles having a size in a nanometer range and particles having a size in a micrometer range;
   (c) extruding a mixture of the polymer material of (a) and the thermally conductive particles of (b) to form a filament of a candidate TCPC material;
   (d) analyzing the filament according to one or more parameters selected from melting temperature of the filament, viscosity of a melt of the filament, suitability of the filament for use in an FFF process, thermal conductivity of the filament, dielectric properties of the filament, resilience of the filament, and spoolability of the filament;
   (e) based on the analyzing of (d), revising the polymer material selection of (a) and/or the thermally conductive particle selection of (b) and repeating steps (c) and (d) with the revised selection(s) until one or more of said parameters is within a desired range for the TCPC material.
29. A three dimensional object resulting from the deposition of a heated filament, the filament comprising the TCPC material of any of claims 1-15.
30. A three-dimensional printing process comprising the steps of
   (a) heating a filament comprising the TCPC material of any of claims 1-15;
   (b) extruding the filament from a nozzle;
   (c) depositing the extruded filament to form a three-dimensional body, wherein the body has a geometry that is substantially identical to a digital design file that is used to program the three dimensional printing process.

### BRIEF DESCRIPTION OF THE DRAWINGS

FIG. 1A shows diagrammatically how the compositional design of a thermally conductive polymer composite (TCPC) material was conducted using the scheme shown in FIG. 1B, which depicts how a generational approach was used to produce a material that exhibited high thermal conductivity, low-loss dielectric properties, and maintained the resiliency and spoolability to be fused filament fabrication (FFF) processable. FIG. 1C shows the microstructural design of FFF-printed TCPC parts, which includes shear path planning and print orientation, annealing, shear alignment of filler, and surface-template crystallization that were important for the emergence of high thermal conductivity.

FIGS. 2A and 2B illustrate how a hybrid mix of nano and micro hBN platelets improved thermal conductivity without greatly affecting printability metrics.

FIG. 3A shows the thermal conductivity of printed and post-processed G7c parts and highlights significant improvement over neat PLA and substantial anisotropy. FIG. 3B shows a plot of the combination of thermal conductivity and electrical resistivity of G7c against relevant extrudable materials, highlighting its potential as a thermal management material for RF applications. FIG. 3C shows an overview of key performance metrics used in the generational compositional design of the G7c TCPC formulation, including high thermal conductivity and low-loss dielectric properties, while maintaining sufficient resilience and spoolability enabling FFF processability. FIG. 3D is a micrograph showing that the FFF printing process shear aligns the hBN platelets parallel with interlayer interfaces creating strong and weak thermal axes, as visualized in the associated diagram. The oriented platelets can seed PLA crystallite growth to make a 3-phase composite. Molecular dynamics simulations of a PLA crystallite were used to determine the anisotropic thermal conductivity of the crystallites.

FIG. 4A is a polarized optical microscopy (POM) image showing the prevalence and bridging of PLA crystallites between neighboring surface-tailored hBN platelets within G7c to form a “hetero-percolated” network. FIG. 4B is a schematic demonstration of the advantage of growing a third phase during post-processing to sidestep the higher filler content needed in 2-Phase composites that preclude printability. FIG. 4C presents transmission electron microscopy (TEM) images of microtomed G7c samples, which confirms that crystallites of PLA seed directly from the surfaces of the chemically tuned hBN under employed thermal post-processing procedures (bottom insets). These crystallites are visibly diminished when the G7c samples are thermally quenched from an elevated temperature (top insets). FIG. 4D shows measured strong-axis data of G7c at different crystallinities is shown. Higher X_{c} value is underpredicted by a layered Lewis-Nielsen (L-N) model (solid line). In comparison, a hetero-percolation model incorporating crystalline bridging effects captures the boost to thermal conductivity that hetero-percolation can impart (dashed line).

FIG. 5A is a schematic illustration of FFF-printed heatsinks with print path planning to maximize thermal conductivity in the direction of the fixed fins. The G7c heatsink is compared to machined aluminum. FIG. 5B shows a comparison for a 5 W heating load of passive and active cooling equilibrium temperatures relative to ambient (Max ΔT) showing experimental results for G7c, neat PLA, and aluminum, as well as FEA simulation results. The inset shows a head-to-head comparison of aluminum and G7c heatsinks when the cooling temperatures are normalized by density. FIG. 5C shows FEA simulation results for Max ΔT across common applications, parameterizing heat flow and convection boundary conditions in reference to Si and GaN integrated circuit (IC) thermal limits.

FIGS. 6A-6B show key compositional effects on relevant thermal and mechanical properties for formulated TCPCs. FIG. 6A shows the effect of modulating volume fraction and matrix identity, and FIG. 6B shows how compositional evolution is informed by composite conductivity, spoolability, and resilience.

FIG. 7A shows a neat hBN platelet with weak interaction to the ESBO and PLA. FIG. 7B shows an OH-derivatized hBN platelet with higher interaction to ESBO and PLA. FIG. 7C shows FTIR results confirming successful OH surface treatment of hBN platelets. FIG. 7D shows that the addition of OH surface treatment in the creation of G5a resulted in noticeable gains across key performance metrics.

FIG. 8A shows graphic representations of each expected interaction between additives/matrix and the silane treatment of the hBN platelets. FIG. 8B shows FTIR results for each surface treatment tested. FIG. 8C shows that APTS, which had the highest amount of PEO ligands, synergistically worked to order the PLA matrix of G7c to improve thermal conductivity drastically.

FIG. 9A is a generational map of weak-axis conductivity outcomes from different TCPC compositional changes. FIG. 9B shows spoolability and resilience of TCPC generations.

FIG. 10 shows that thermal post-processing controllably increased the percent crystallinity within G5a, G6a, G6b, and G7c and presents the relationship between thermal conductivity and crystallinity of the PLA matrices.

FIG. 11 is a diagram relating the strain of spooling (ε_{Sp}) to the maximum strain experienced by a filament (ε_{b}) for the calculation of spoolability (Sp) in the main text.

FIG. 12 shows the extruder assembly that was tested with the original and new heat-break fans. Multiple thermocouples were added to the assembly to measure the thermal differences when the heater-block was set to isotherm at 240° C. and 210° C. G5a was pressed through the assembly prior to measurements.

FIG. 13 is a schematic representation of the hard teeth of the steel hob feeding gear which can shear away a portion of the incoming filament, ultimately halting flow during printing.

FIG. 14 shows a friction feed modification to the TAZ6 print head assembly that avoids potential filament “chew-out”.

FIG. 15 shows that the crystallinity of G7c was increased the most under a 135° C. annealing isotherm.

FIG. 16 shows results obtained when composite variant G5a was annealed at various temperatures below and above the composite's melt temperatures. The resulting thermal conductivities did not change much from as-printed.

FIG. 17A is an image of a microtome apparatus used on a G7c filament, oriented such that the blade cuts perpendicular to the filament's cylindrical axis. FIG. 17B is a TEM micrograph of a cut section indicating pervasive micro-tearing and void formation down to the sub-micron level (inset). FIG. 17C is a schematic indicating microstructural orientation during the microtome sectioning process, likely leading to the voids seen in the TEM micrograph.

FIG. 18 shows a representative TEM micrograph of a small section from the G7c-PP filament. Note the four components: APTS-treated hBN (green lines), untreated nano-hBN, crystalline PLA, and amorphous PLA. In addition, the morphological transition from amorphous to crystalline PLA can be seen on the left of the image (arrow).

FIGS. 19A-19B show TEM micrographs of (FIG. 19A) fractured APTS-treated hBN emanating from PLA matrix with local crystalline polymer regions and (FIG. 19B) a large region of crystalline PLA connecting amorphous regions and with a portion of APTS-treated hBN behind. Note the fracture characteristics of the “brittle” materials (crystalline PLA, hBN) compared to the ductile amorphous PLA.

FIGS. 20A-20D show TEM micrographs of microtomed G7c-PP after melting and quenching to eliminate crystallinity. FIG. 20A shows an ATPS-hBN platelet bridging two PLA-rich regions, and FIG. 20B is a higher magnification of the inset of the platelet surface from FIG. 20A. FIG. 20C shows a PLA-rich region with various nano and micro-hBN debris, and FIG. 20D shows a higher magnification of the inset of FIG. 20C indicating no morphological matrix differences around the hBN.

FIG. 21 shows (left) All analytical models presented against the recorded strong-axis data of G7c, and (right) schematically represented assumptions relevant to each model herein.

FIG. 22 shows the function R(x_{c}) increasing with increasing percent crystallinity of the composite matrix. This relationship when applied to a law of fractions model provided a good fit to measured data.

FIG. 23 shows a schematic representation of the heatsink tester, which used a FFF printed enclosure of PETG and was controlled by a Raspberry Pi 2B with various control boards.

FIG. 24 illustrates that, with optimal surface quality, the G7c filament was easily spooled around a 100 mm diameter filament reel. However, irregular flow rates and temperature profiles made it difficult to achieve consistent filament at scale.

FIG. 25 shows print sample orientations used to measure through and in plane thermal conductivities.

FIG. 26 shows the effect of print direction on thermal conductivity. Strong axis heat transfer is far greater than weak axis transfer.

FIG. 27 shows that a low-temp annealing post-process increased G7c percent crystallinity, which drastically increased the composite variant's strong axis thermal conductivity (G7c-PP).

### DETAILED DESCRIPTION

The present invention provides the use of fused filament fabrication (FFF) to economically produce geometrically complex thermal management parts, as well as dielectric composite filament materials that are highly thermally conductive and FFF processable. The materials provided utilize filler distributions, surface chemistries, and polymeric conformation to achieve filaments that exhibit thermal conductivities as large as metallic thermal interface pastes while still being dielectric and printable.

These filaments can be used for common electronic and radiofrequency device applications to produce heat sinks that cool as effectively as their heavier metal counterparts currently in use in industry.

### Design Approach

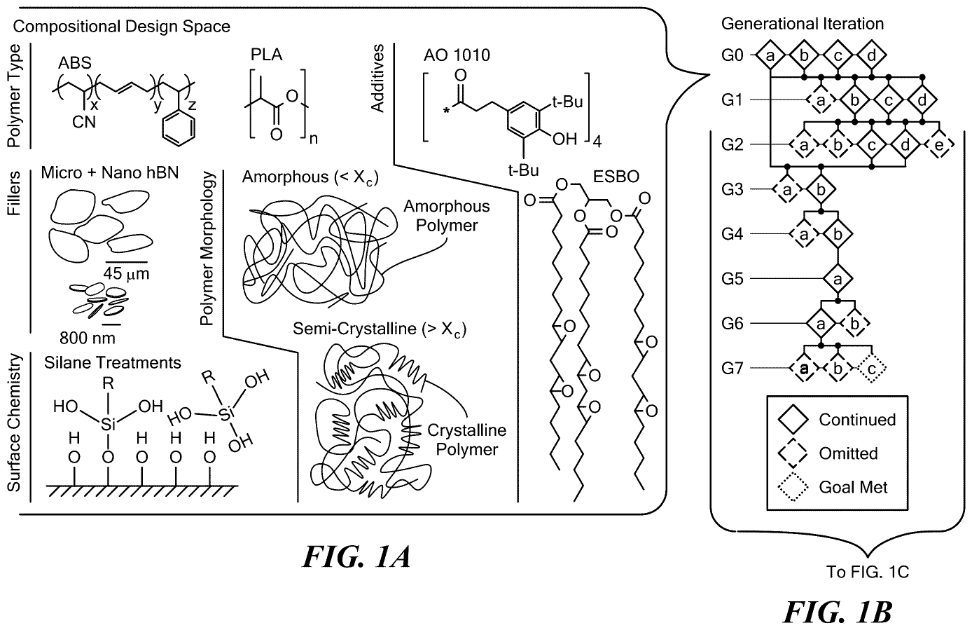

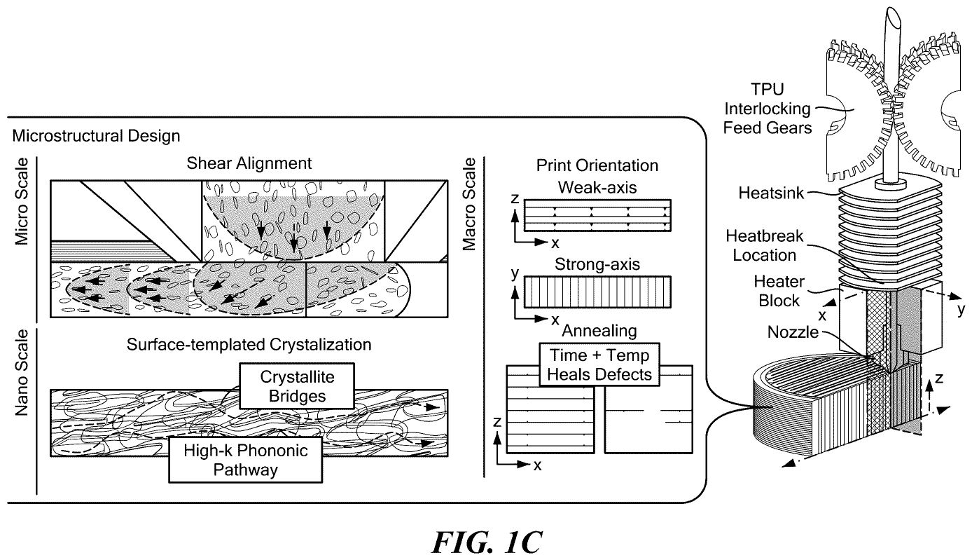

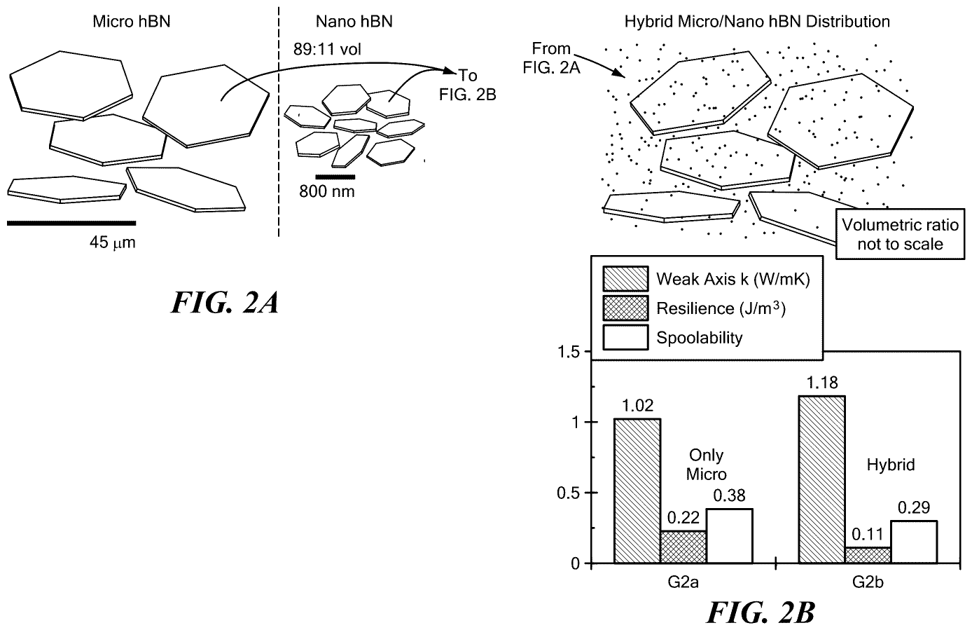

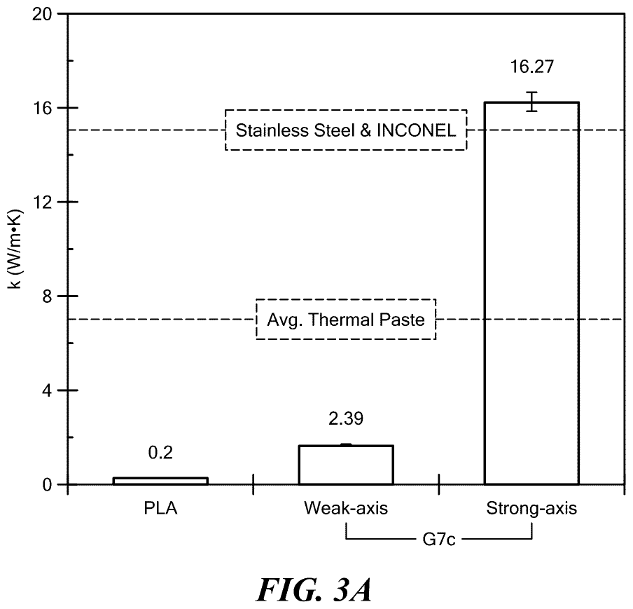

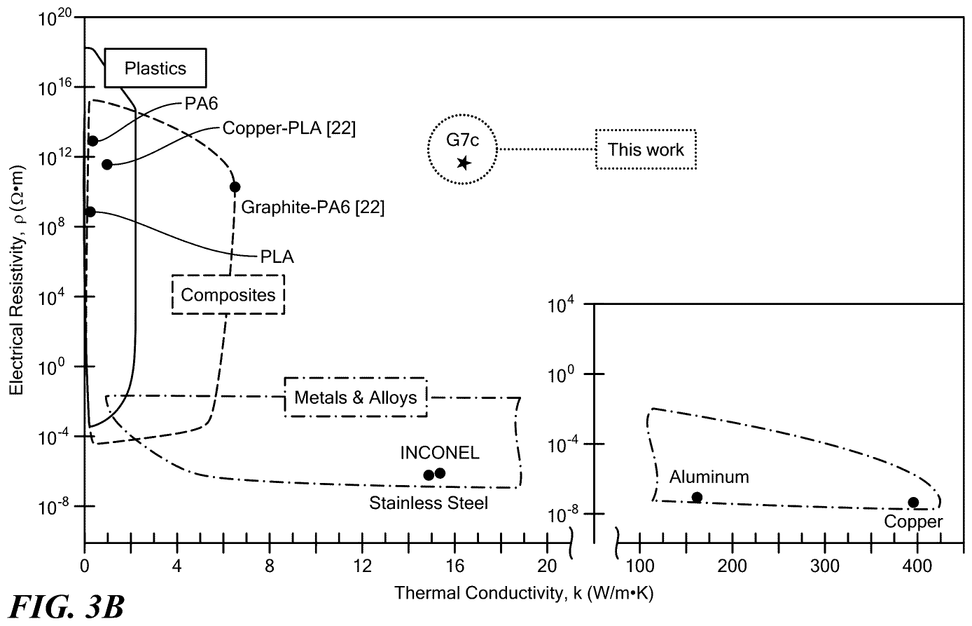

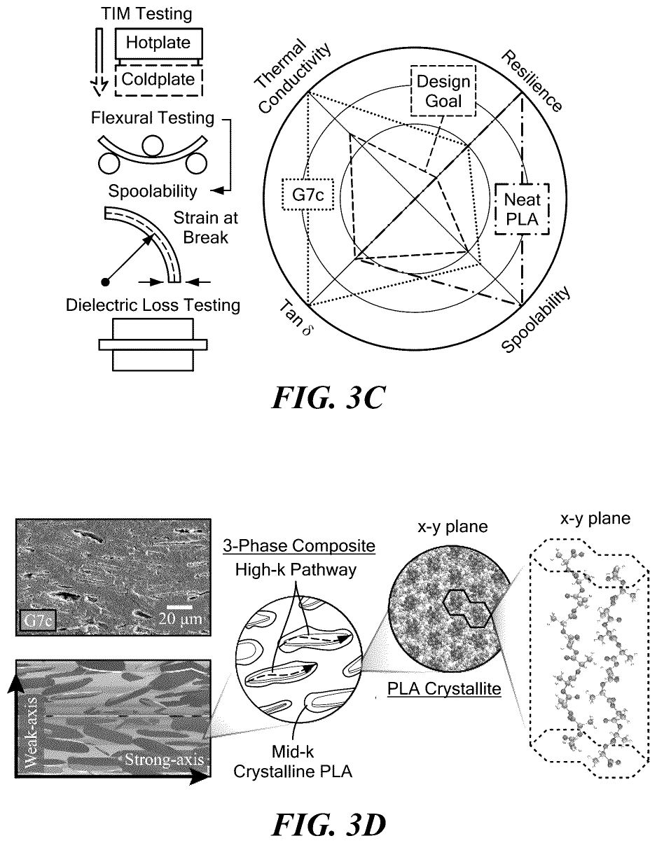

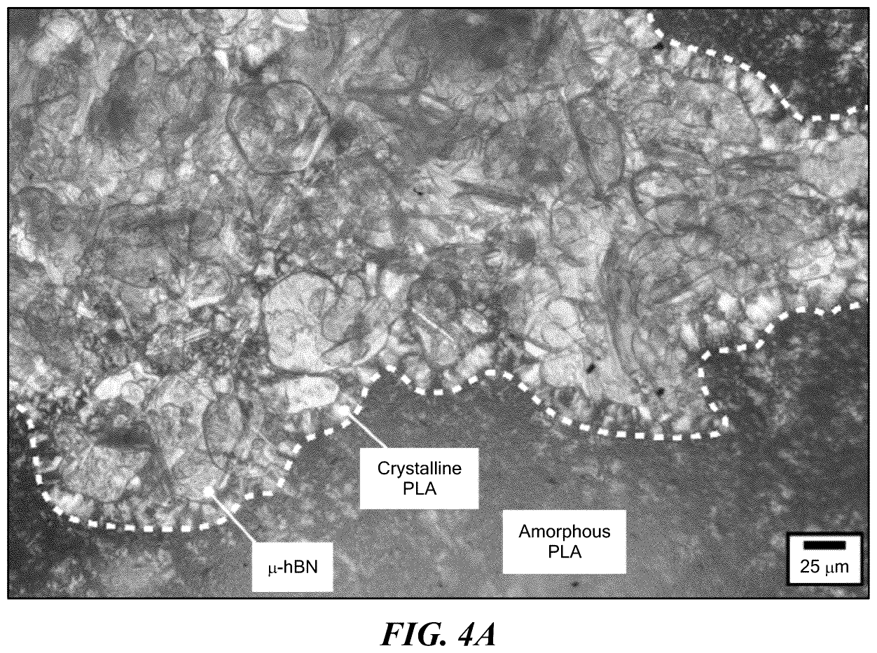

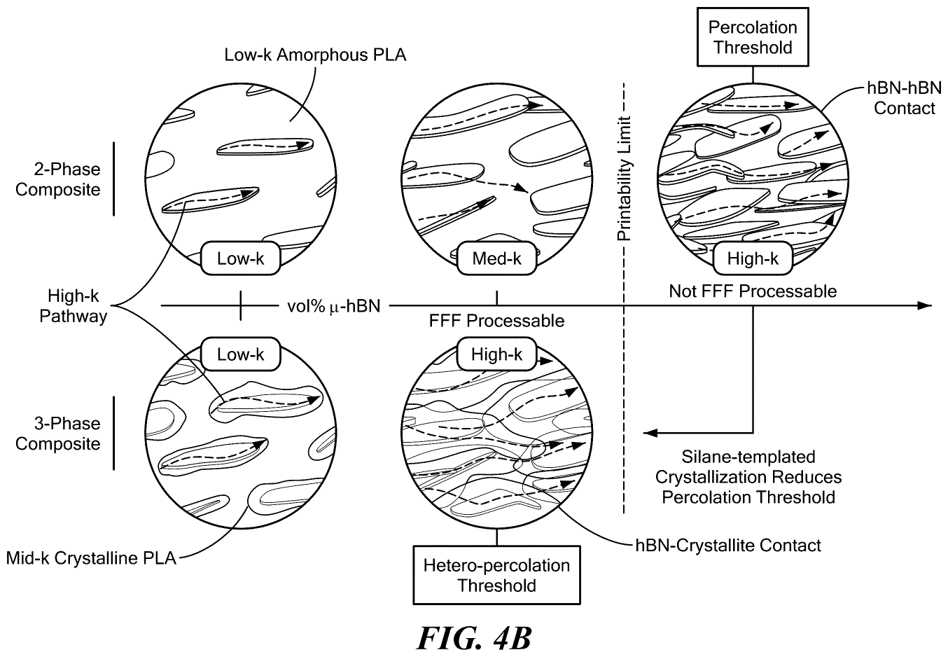

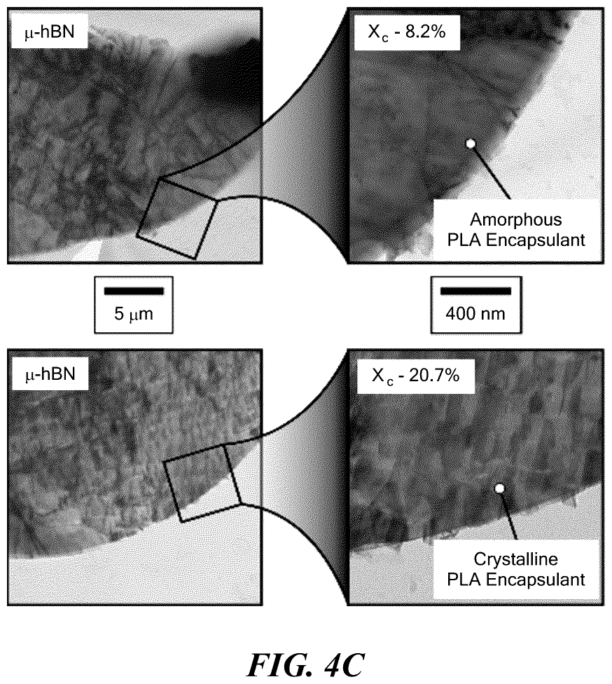

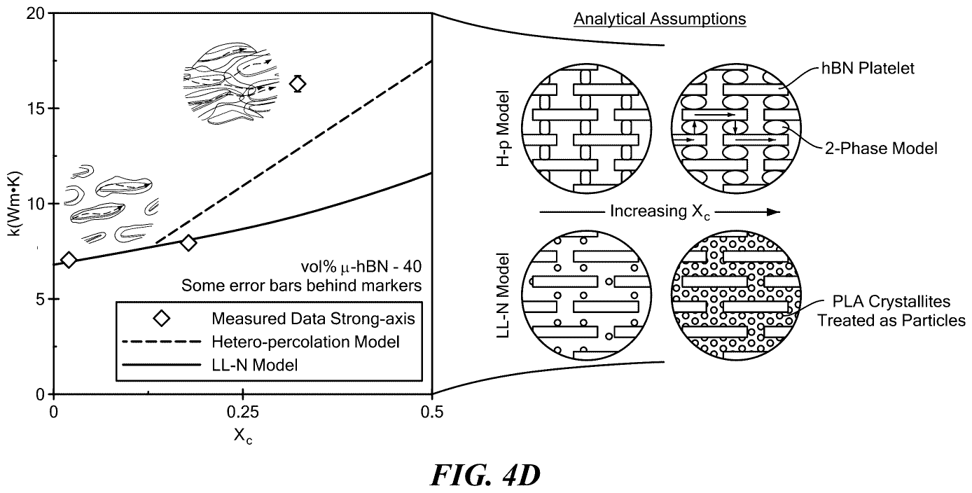

An evolutionary design approach was used to map compositional and process development against key performance indicators (see Error! Reference source not found. and FIG. 3). Incremental compositional changes to a materials class of TCPC filament were investigated, including the particle package (including both 45 μm and 800 nm diameter hexagonal boron nitride platelets), the carrier polymer (including ABS and PLA), printability additives like antioxidants, plasticizer (including epoxidized soybean oil) lubricants, and surface chemistries (including hydroxylation and silanization). Process variables also were investigated, including printing parameters and thermal post-processing steps. In each development cycle, (herein termed a “generation”), the evolved filament was used in printing and part characterization. The key performance indicators tracked included maintaining high electrical resistivity and printability while increasing thermal conductivity. Printability was defined as the ability for the filament to spool around a 200 mm diameter spool (calculated from strain at break) and the ability to be extruded on a gantry system without breaking (later mapped to resilience). Generations of evolutionary design G0 through G7 were performed (FIG. 1B), resulting in modifying a highly printable and dielectric 0.15-0.3 W/mK filament into a highly printable and dielectric 16.27 W/mK filled filament. The thermal conductivity was typically evaluated in the work described herein along the weak axis, as the printed part was significantly easier and faster to manufacture. In addition, key generational variants were tested along the strong axis to understand the thermal conductivity relative to other materials in use.

The effects of build orientation and path planning were leveraged to control the directionality of the inherent anisotropy within printed parts due to the anisotropic hBN platelets and the orientation and prevalence of print interfaces from the FFF process (FIG. 1C). Weak-axis and strong-axis samples were printed so that print traces were perpendicular or parallel, respectively, to the direction of conductivity characterization. Shear-induced particle alignment was leveraged to align hBN along the print. Layer height was selected to be 250 μm, the lowest value that could be consistently printed to maximize shear orientation effects.

Thermal post-treatments were undertaken between Tg and Tm to heal interfacial voids and print defects without altering part geometry. In TCPCs with a semi-crystalline matrix, thermal post-processing above the crystallization temperature followed by slow-cooling can also promote crystal growth. Crystalline polymer bridges between neighboring hBN platelets are believed to result in hetero-percolation that enables emergent thermal conductivity significantly greater than previously seen within printable TCPCs. As used herein, the term “hetero-percolation” refers to the combined transmission of thermal energy between adjacent polymer crystallites, between adjacent particle inclusions, such as hBN platelets, and between adjacent crystallites and particle inclusions. The existence of hetero-percolation can be ascertained or inferred structurally by the presence of tight packing of crystallites and/or particle inclusions, some of which are in contact with adjacent crystallites and/or particle inclusions, as seen with a polarized microscope or an electron microscope, or functionally by the presence of high thermal conductivity, such as thermal conductivity of at least 5, at least 6, at least 7, at least 8, at least 9, at least 10, at least 11, at least 12, at least 13, at least 14, at least 15, or at least 16 W/m·K. The presence of such crystallites is associated with dramatically increased thermal conductivity, as corroborated by the crystallite bridging models described herein.

Four key metrics were used to guide formulation and process design: thermal conductivity, resilience, spoolability, and low-loss dielectric properties (FIG. 3C). Additional qualitative factors such as extrudability, surface quality, and general ease of printing were also considered during the evaluation process.

Spoolability (Sp): The ability of a filament of diameter D_{F} to be wrapped around a spool of diameter Dₛ to supply the FFF process, defined as Sp=ε_{b}/ε_{Sp}=ε_{b}[(D_{Sp}/D_{F}+1)], where ε_{b} is the measured strain at break and ε_{Sp} is the calculated strain of spooling. Filaments with Sₚ>1 are desired, as filaments with Sₚ<1 will likely break during spooling. FFF printers commonly employ spools of D_{Sp}˜200 mm and filaments of D_{F}˜3 mm. For a typical unfilled polymer, strain at break is at least ε_{b}>0.1, resulting in values of Sₚ˜7.

Resilience (J/m³): Mechanical toughness of a filament calculated by integrating the stress-strain curve during flexural testing until yield or break. Filaments with higher resilience were found to be correlated with lower amounts of brittle surface erosion between the drive gears during the FFF feeding process.

Thermal conductivity (W/m·K): Measured using thermal interface material (TIM) testing primarily along the weak thermal axis for easier screening of as-printed TIM discs (33 mm diameter, 1-4 mm thickness). Strong-axis thermal conductivity is only reported for select compositions due to the challenging printing requirements. Improvements in weak-axis conductivity have been found to correlate with strong-axis improvements, both in prior TCPC studies [52] and in the inventors' own data set, particularly as a consequence of increased polymer crystallinity or enhanced polymer-hBN interfaces.

Low-loss dielectric properties: Dielectric constant and loss tangent were tested for key composite generations. All TCPC constituents (polymer matrix, hBN particles, and additives) are inherently dielectric (not electrically conductive) materials, establishing dielectric composite behavior across all compositions.

### Tailoring the Filler Concentration to Enhance Thermal Conductivity (G0-G3)

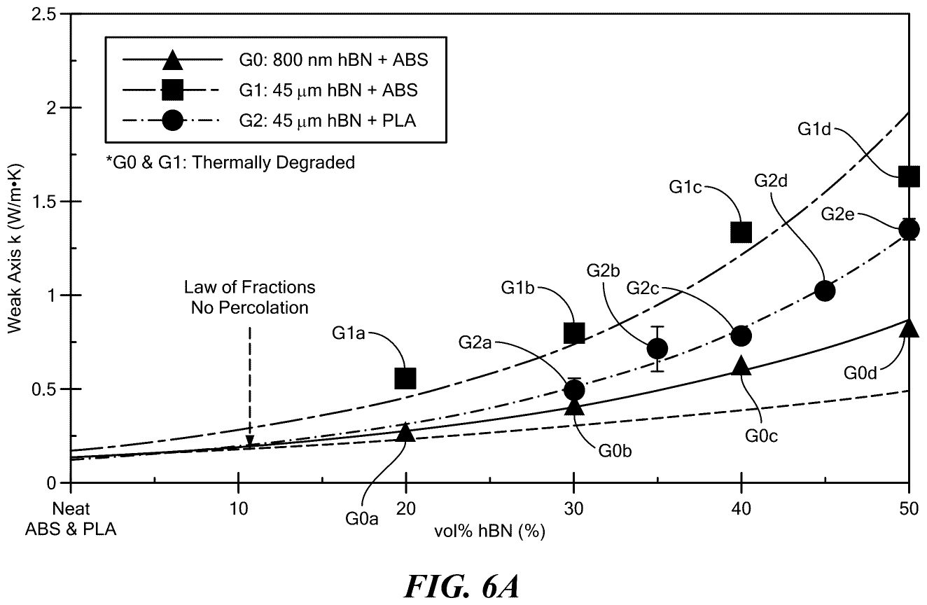

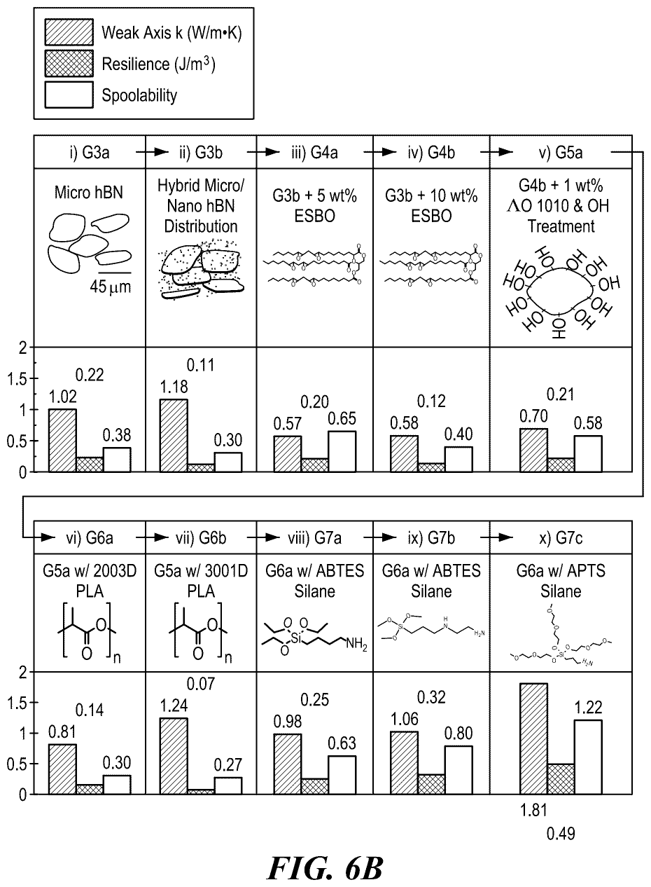

For the baseline composition, generation zero (G0), a highly printable and dielectric acetonitrile butadiene styrene (ABS) matrix (0.17 W/mK) was used. To this, an increasing vol % of thermally conductive and dielectric hBN platelets was added to form TCPCs. Eight hBN-ABS variants (G0a-d and G1a-d) where investigated, in which ABS was solvent cast and extruded with varying levels of 45 μm hBN platelets (G1a-d) or 800 nm hBN platelets (G0a-d). The thermal conductivity across these variants is shown in FIG. 6A. Of note, 800 nm hBN platelets have been investigated previously and their results here match well [43]. It was discovered that the 45 μm hBN platelets demonstrated a considerable improvement relative to the 800 nm platelets including a high weak-axis thermal conductivity of 1.63 W/mK at 50 vol % loading of 45 μm hBN in ABS. This increase to 858% of the original ABS thermal conductivity is likely made possible by the uninterrupted phononic transport of the larger 45 μm hBN platelet atomic structure. Unfortunately, the printability of G0-1 variants suffered with the increase in thermal conductivity. There was a clear trait-tradeoff that would prevent application usefulness of this generation. A simple pass-fail was recorded for each G0-1 variant as to whether the composite system could be extruded into filament with their single screw extruder. G0-1 variants that had a maximum of 40 vol % hBN filler were extrudable into filament; however, only the variants with 30 vol % or lower were able to survive the FFF process. The 50 vol %, and the 40 vol % (after repeated extrusion) G0-1 variants gelled under filament extrusion conditions and rapidly degraded. Based on TGA of the neat ABS matrix and some high vol % G0-1 variants, it was apparent that the butadiene within the ABS co-polymer was thermally degrading at reduced temperatures under the high shear within the filament extruder.

The low thermal processability of the G0 and G1 ABS matrix was limiting their ability to pursue higher thermal conductivities. For the evolution of G2 the polymer matrix was switched to PLA (0.2 W/mK), another ubiquitous FFF feed stock. This polymer was not a co-polymer and was considered to have a more predictable thermal processability [44]. The relationship between weak axis thermal conductivity and vol % 45 μm hBN filler was determined via TIM for the new hBN-PLA generation (G2). The exponential percolation relationship recorded was similar to the rate of increase for G0-1 but slightly transposed downward, highlighting that the effect of increasing 45 μm hBN filler was agnostic; however, the polymer matrix mattered (Error! Reference source not found). G2 variants with 50 vol % or lower hBN filler were extrudable into filament and all variants with 40 vol % or lower hBN were FFF processable. To improve thermally conductivity without significant detriment to the printability (via increased viscosity), the 5 vol % 800 nm hBN with 40 vol % 45 μm hBN were combined within the PLA matrix to create G3b. The added nano hBN may provide a way to get phonons between percolated micron hBN pathways to transfer heat more effectively. Such approaches have been explored in the past to maximize solids content by adding smaller particles that can fit effectively within the interstitial spaces of larger particles. This hybrid filler sized variant had the highest thermal conductivity recorded thus far, 1.18±0.01 W/m·K, while maintaining decent processability both for filament extrusion and for FFF. The printability of G3a and G3b was assessed by the recorded resilience and calculated spoolability from 3-point bend testing. G3a had a resilience of 0.22±0.03 J/m³ and was able to withstand the steel hob feeding gear on the print head assembly, though it was not spoolable. G3b had a lower resilience than G3a at 0.11±0.02 J/m³ and was neither spoolable nor could withstand the hob gear. Seeing that both variants were not highly printable, the particle package that led to the highest thermal conductivity (G3b) was carried through to the next generations.

### Tailoring Additives to Enhance Printability (G4)

Generation G4 incorporated the lubricant/toughening agent epoxidized soybean oil (ESBO) and the antioxidant Antioxidant 1010. Previous published works have found that 10-20 wt % ESBO in PLA have the best outcomes in terms of polymer strength and ductility [45] and 1 wt % Antioxidant 1010 (a high molecular weight indered phenolic antioxidant) to PLA is an industry standard to improve the polymer's resistance to thermal degradation during filament creation and later FFF processing [46]. To minimize the potential impact of ESBO on thermal conductivity, 5 wt % (G4a) and 10 wt % (G4b) ESBO (relative to wt of PLA) composite variants were investigated. G4a exhibited a reduce thermal conductivity of 0.57 W/mK and was not spoolable, but was able to withstand the steel hob gear, with a resilience of 0.20±0.05 J/m³. G4b exhibited a similarly reduced weak-axis thermal conductivity of 0.58±0.03 W/mK; however, the composite variant had a reduced resilience of 0.12±0.04 J/m³ and was not spoolable or able to withstand the steel hob gear. Since both variants of G4 were similar in the key characteristic of thermal conductivity, the additives within the G4b variant were selected to continue to the next generation due to the established mechanical benefits of 10 wt % ESBO to PLA by others.

### Hydrogen Bonding to Enhance Thermal Conductivity & Printability (G5a)

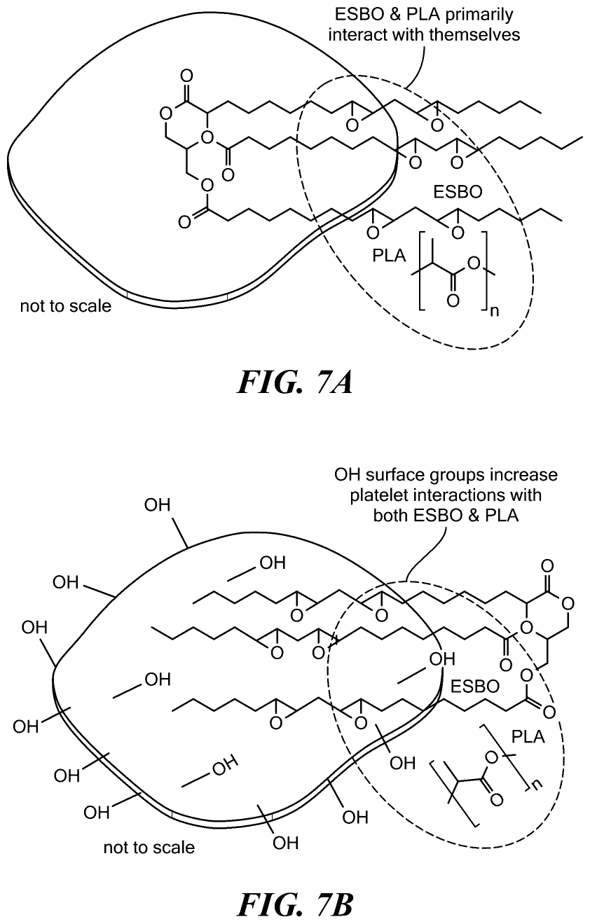

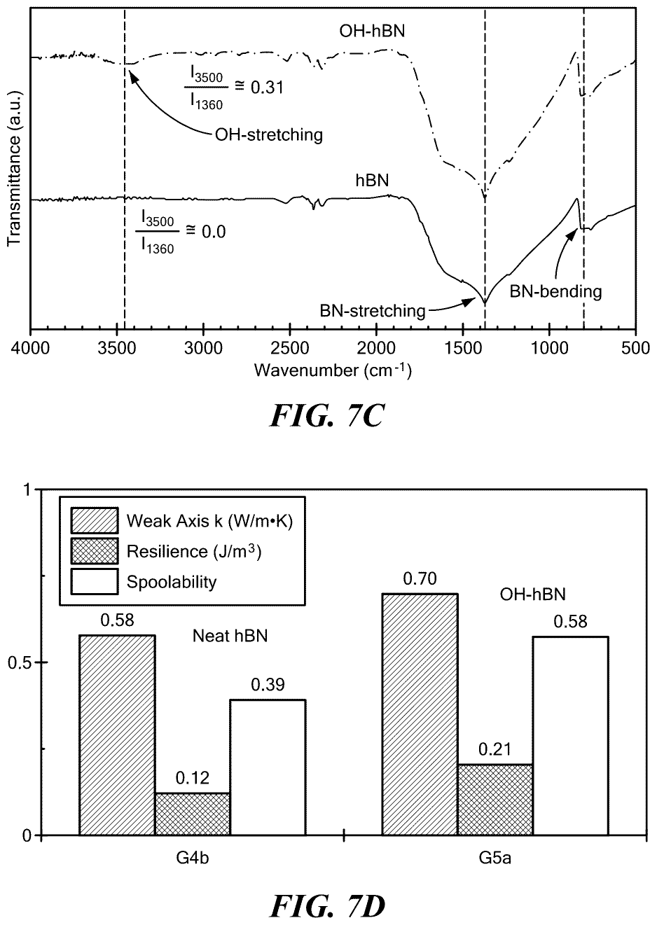

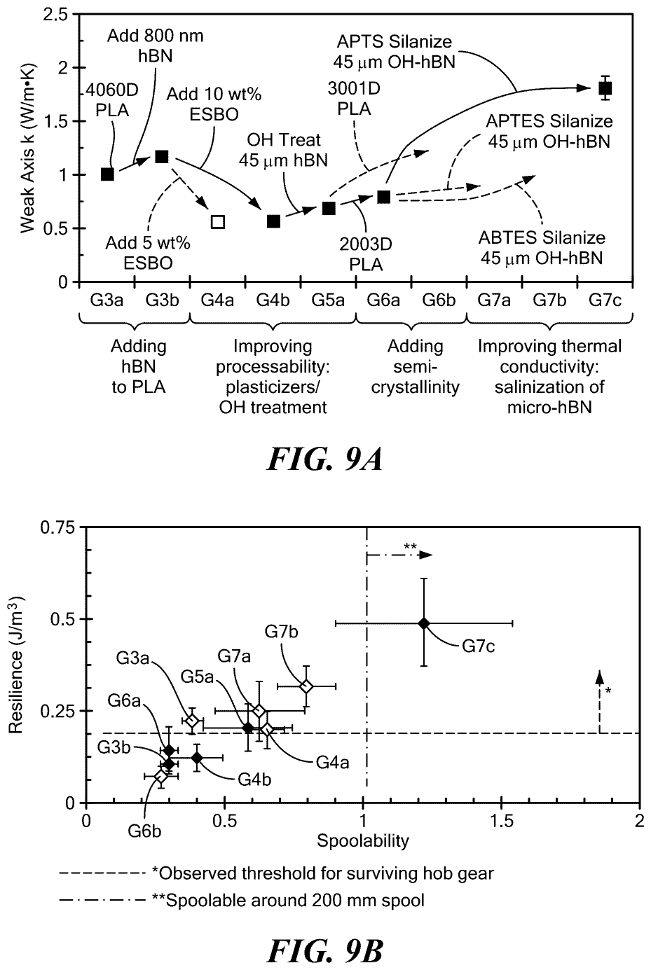

Tuned surface chemistry can enable filler to interact with a polymeric carrier more intimately, and can help drive conformational changes in the polymer like crystallization. Several surface chemistries were explored in this work including hydroxylation and silanization. Generation G5a incorporated the hydroxylation of the 45 μm hBN platelets. Hydroxylation (the addition of OH groups) of the hBN micro-platelet surfaces would increase the secondary hydrogen bonding interactions of the platelets with both the PLA matrix and the ESBO epoxide groups [45]. Previous procedures used by others for hydroxylation are complex [47]. Here, a much simpler method was used to hydroxylate hBN platelets that relies on OH group adsorption via a base bath of NaOH solution at an elevated temperature. Using Fourier transform infrared (FTIR) spectroscopy, successful hydroxylation was validated at similar levels to the more complex procedures (FIGS. 7C, 7D). G5a demonstrated a much-needed increase in the weak-axis thermal conductivity to 0.70±0.02 W/mK, while also improving in resilience and spoolability: 0.21±0.06 J/m³ and 0.58±0.16, respectively (FIGS. 9A, 9B). The clear benefits of hydroxylating the surfaces of the 45 μm hBN platelets were carried through to all future generations of composite.

### Exploring PLA Configuration and Conformation to Enhance Thermal Conductivity (G6)

Previous work has demonstrated the importance of crystallizable content within the TCPC matrix. Ordered polymeric chains within spherulites act as stiff vibrational sections that can more easily transfer phonons from filler to filler compared to less stiff and vibrationally dampening amorphous polymer regions [48]. To assess the effects of semi-crystalline polymer matrices within their hBN-PLA composites, the two other variants of PLA were explored (G6): the high molecular weight and slightly crystalline 2003D PLA (G6a), and the lower molecular weight and highly crystalline 3001 D PLA (G6b). Details of all three relevant generations are offered below in Table 1. The 2003D PLA had a M, of 183850±1000 g/mol which was very similar to the M, of the amorphous 4060D PLA, 181600±5300 g/mol. This fact allowed for the isolation of the effects of crystallinity on the thermal conductivity and on the processability of their hBN-PLA composites. Compared to G5, G6a had an improved weak axis thermal conductivity of 0.81 W/m·K; however, the new composite variant had a reduced resilience and spoolability of 0.14±0.06 J/m³ and 0.29±0.03, respectively. Reducing M, of the PLA within G6b resulted in a further improvement to thermal conductivity of 1.24±0.03 W/mK. Both improvements to thermal conductivity can be attributed to the increase in percent crystallinity within the polymer matrices of G6a and G5b (Table 1). G6b spoolability was similar to that of G6a at 0.27±0.06, though G6b resilience was greatly reduced and was the lowest recorded within this work: 0.07±0.03 J/m³. Though the thermal conductivity of G6b was far higher than that of G6a, G6b was locked in a gelled state of high crystallinity due to 3001 D's low M_{w} and was not able to be processed via FFF. Therefore, the 2003D matrix was carried through to later generations of composite.

TABLE 1
DSC and GPC results for composite generations G5a-G6b,
both after solvent casting and filament extrusion.

| | | | | | | | X_{c} (%) | X_{c} (%) |
|---|---|---|---|---|---|---|---|---|
| | PLA | M_{w} | | T_{g} | T_{c} | Tₘ | after −20° | after −1° |
| Generation | ID | (g/mol) | Condition | (° C.) | (° C.) | (° C.) | C./min | C./min |
| G5a | 4060D | 181,600 ± | Fresh | 56 ± 1 | — | — | 0 | 0 |
| | | 5300 | Filament | 54 ± 3 | — | — | 0 | 0 |
| G6a | 2003D | 183,850 ± | Fresh | 57 ± 1 | — | 149 ± 1 | 6.3 | 27 |
| | | 1000 | Filament | 58 ± 4 | 114 ± 8 | 149 ± 1 | 0.2 | 26.9 |
| G6b | 3001D | 85,801 ± | Fresh | 58 ± 3 | 103 ± 13 | 165 ± 2 | 33.4 | 43.6 |
| | | 1500 | Filament | 51 ± 1 | 108 ± 17 | 162 ± 1 | 43.4 | 41.7 |

### Exploring Covalent Chemistry to Enhance Thermal Conductivity (G7)

Covalent surface chemistries, like silanes, have the promise for coupling the atomic vibration from the hBN basal plane through stiff covalent bonds to the polymeric matrix, minimizing the phononic dispersion that can happen at materials interfaces [49]. Three silane molecules were chosen to covalently attach to the surfaces of the 45 μm OH-hBN platelets via a hydrolysis reaction: APTS, APTES, ABTES. These three silanes were chosen for their reported interactions with epoxide groups and with PLA matrixes [50]. FTIR was used to confirm the success of each surface treatment reaction. Success was determined by comparing the spectra of the silanized OH-hBN to the spectra of the neat OH-hBN such that there was no longer an adsorption feature for hydroxyl groups, as the silanization reaction should chemisorb the silane groups to the available OH groups [50].

Generations G7a, G7b, and G7c had either the silane ABTES, APTES, or APTS chemisorbed to the surface, respectively. The weak axis thermal conductivity of generations G7a, G7b, and G7c were as follows: 0.98±0.02 W/m·K, 1.06±0.04 W/m·K, 1.81±0.11 W/m·K. G7c showed a considerable increase in thermal conductivity compared to the G7a or G7b. Examining the structures of each silane in Error! Reference source not found. shows that the presence of polyethylene oxide (PEO) repeat units in seems to positively correlate with the resultant thermal conductivity of each composite generation.

PEO has been used as a plasticizer within PLA to increase the base polymer's crystallinity [51]. This effect was confirmed via their DSC results for generation G7's fresh samples' X_{c} Ratios of fast cool X_{c} to slow cool X_{c}—PEO content notably increased the X_{c} Ratio (Table 2). The increases in crystallinity increase the overall amount of rigid covalent network for the easy transfer of phonons. Specifically, around the inter-phase of the surface treated hBN and PLA matrix interface, where the most phononic transfer can be dispersed.

TABLE 2
DSC of G7a-c in relation to number of PEO
repeat units within each silane molecule.

| | | | | | X_{c} (%) | X_{c} (%) | | # of |
|---|---|---|---|---|---|---|---|---|
| | | T_{g} | T_{c} | Tₘ | after −20° | after −1° | X_{c} | PEO |
| ID | Condition | (° C.) | (° C.) | (° C.) | C./min | C./min | Ratio | units |
| G7c | Fresh | 60 ± 3 | 111 ± 3 | 147 ± 1 | 7.5 | 26.1 | 0.29 | 6 |
| | Filament | 58 ± 3 | 115 ± 9 | 145 ± 2 | 8.2 | 20.7 | 0.40 | |
| G7b | Fresh | 57 ± 2 | 115 ± 9 | 147 ± 2 | 2.8 | 25.7 | 0.11 | 0 |
| | Filament | 58 ± 1 | 114 ± 9 | 147 ± 1 | 8.4 | 30.8 | 0.27 | |
| G7a | Fresh | 59 ± 2 | 115 ± 16 | 147 ± 2 | 6.6 | 24.8 | 0.27 | 0 |
| | Filament | 57 ± 1 | 116 ± 12 | 147 ± 2 | 7.9 | 28.3 | 0.28 | |

The resiliencies of each G7 variant were as follows: G7c was 0.49±0.12 J/m³, G7b was 0.32±0.05 J/m³, G7a was 0.25±0.08 J/m³. G7c had the highest recorded resilience within this work. This composite variant's impressiveness was furthered by its high spoolability of 1.20±0.32. G7b and G7a had spoolabilities of 0.79±0.10 and 0.62±0.16, respectively. G7c was a high performing filament derived from this evolutionary process, given it exhibited the highest recorded weak axis thermal conductivity, resilience, and spoolability of any composite herein.

### FFF Processing Parameters of G5a and G7c

The print parameters used to create FFF parts with the G5a and G7c composite variants are tabulated below in Table 3. These settings produced consistent print samples; however, the G5a and G7c samples adhered too well to the print bed material and they needed to be printed on an easily removable surface, like aluminum foil held down to the bed via a layer of PVA. Further, a layer of PVA on top of the aluminum foil was required to achieve proper bed adhesion during the first print layer.

TABLE 3
FFF print parameters for the G5a and G7c hBN-PLA TCPCs.

| | Print | Bed | Print | Layer |
|---|---|---|---|---|
| Comp. | Temp. | Temp. | Speed | Height |
| ID# | (° C.) | (° C.) | (mm/s) | (μm) |
| G5a | 210 | 65 | 30 | 250 |
| G7c | 250 | 65 | 50 | 250 |

### Exploring Print Orientation to Enhance Thermal Conductivity

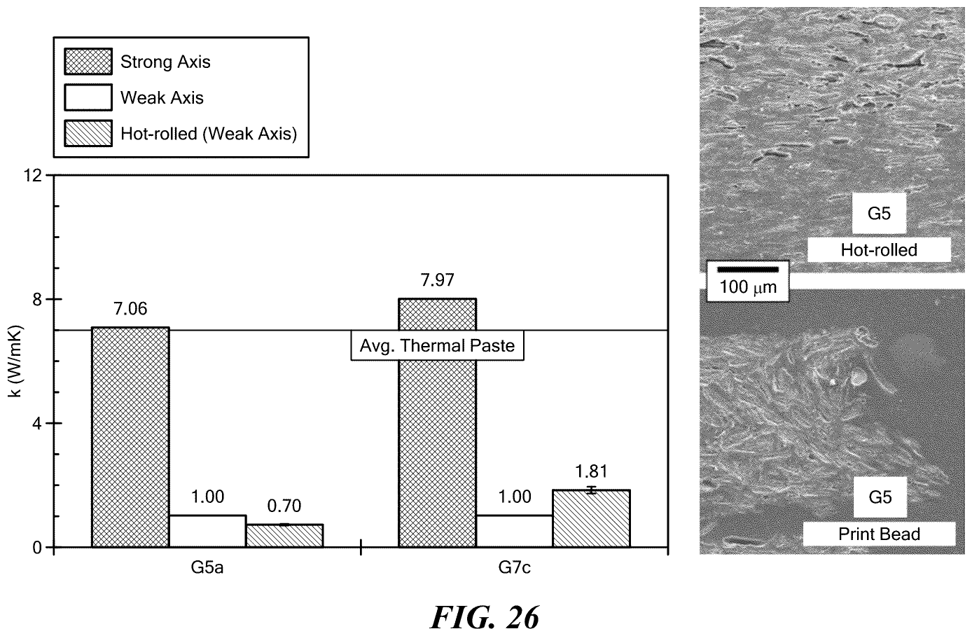

Print orientation played a major role in the emergent performance of both the thermal conductivities of the G5a and G7c composites (Error! Reference source not found). Weak axis and strong axis printed samples were created for TIM testing. The weak axis conductivity of the printed G5a samples was higher than their hot-rolled counterparts. This was due to how the print bead was layered. Each bead was an oblong and flattened ellipsoid. The shear within these print beads orients most platelet filler particles along the print direction, but not all. Some hBN platelets are seen oriented concentrically to the outer curvature of the print bead shape (FIG. 26), which means that some conductive filler was oriented in the direction of TIM testing (i.e. along the strong axis).

The strong axis printed samples were considerably more conductive than their weak axis counterparts. As previously mentioned, the shear experienced by the exrudate induces alignment and increased percolation of the filler platelets. These ceramic highways of phononic transfer within each print bead lead to increased efficacy in transferring thermal energy.

### Low-Temperature Annealing of G7c Prints

Annealing below the melt temp of a TCPC can greatly improve the composite's thermal conductivity by reducing inter-layer and intra-layer interface thermal resistance and by increasing the percent crystallinity within the polymer matrix. Composite variant G5a was found to not improve in thermal conductivity after annealing, as the composite was wholly amorphous and had minimal print interfaces already after printing. G7c prints also had minimal print interfaces; however, this composite variant was semicrystalline and a post-processing procedure was developed to maximize this TCPC's crystalline content.

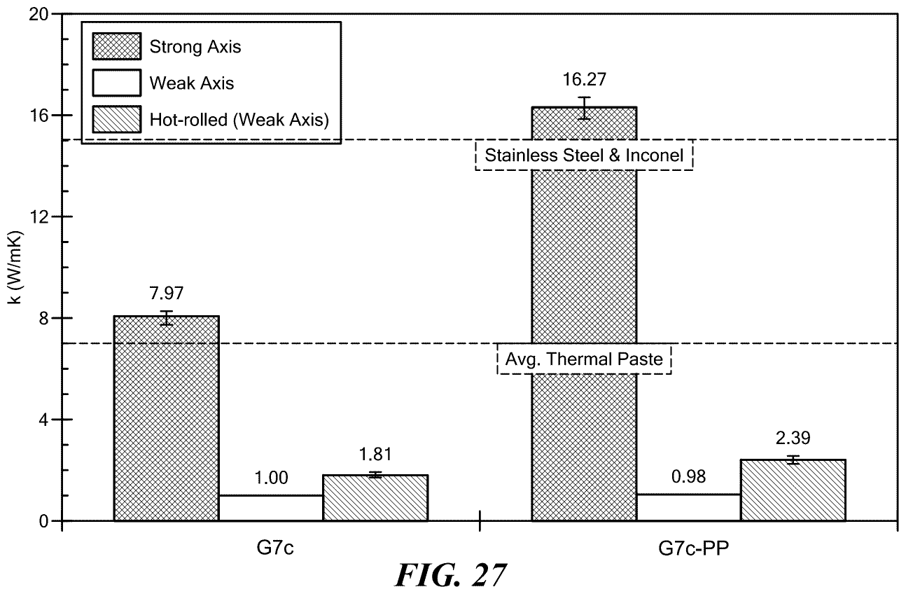

A DSC procedure was run to determine the best annealing temperature to promote the greatest percent crystallinity within G7c. It was determined that an annealing procedure at 135° C. followed by a −1° C./min cool down would promote the highest X_{c} values. To make sure larger prints of G7c were given enough time to fully crystallize at this temperature, G7c prints were held at 135° C. for 4 hours before initiating the −1° C./min cool down. The as-printed G7c percent crystallinity of 18.4% was increased to 34.4% after this 135° C. post processing procedure. The weak axis thermal conductivity after post-processing did increase slightly for the fully dense hot-rolled samples of G7c; however, the printed samples experienced no change (FIG. 27). The increased crystallinity within printed samples of G7c after post processing resulted in an impressive 104% increase in strong axis thermal conductivity compared to the already impressive strong axis as-printed conductivity (FIG. 27). This large increase in strong axis thermal conductivity is consistent with the improvements recorded in previous works for semicrystalline systems with anisotropic fillers. G7c has now been proven to beat out the thermal performance of some key additively manufacturable metal solutions for thermal management.

In general, the formation of crystallites in the polymer material can be promoted or maximized by a thermal post-process (i.e., performed after printing the part) that includes i) heating the material to a temperature below its melting temperature (Tm) for a certain period of time (this serves to melt the majority of the crystallites within the matrix and to additionally anneal the polymer composite and heal the interlayer and intralayer interfaces and internal voids to reduce thermal resistance), followed by ii) slow cooling (e.g., cooling at a rate from about 0.1° C./min to about 5° C./min, through the polymer's crystallization temperature (Tc) and down to the operating temperature for the end part (e.g. room temperature). These transition temperatures will depend on the polymer material and are well known or can be readily determined by routine methods. Different polymer materials will require different cooling rates, with slower cooling rates promoting higher end crystallinity in the composite part which will increase “hetero-percolation” within the microstructure of these composite parts.

### Application Testing of Dielectric TCPCs for Thermal Management

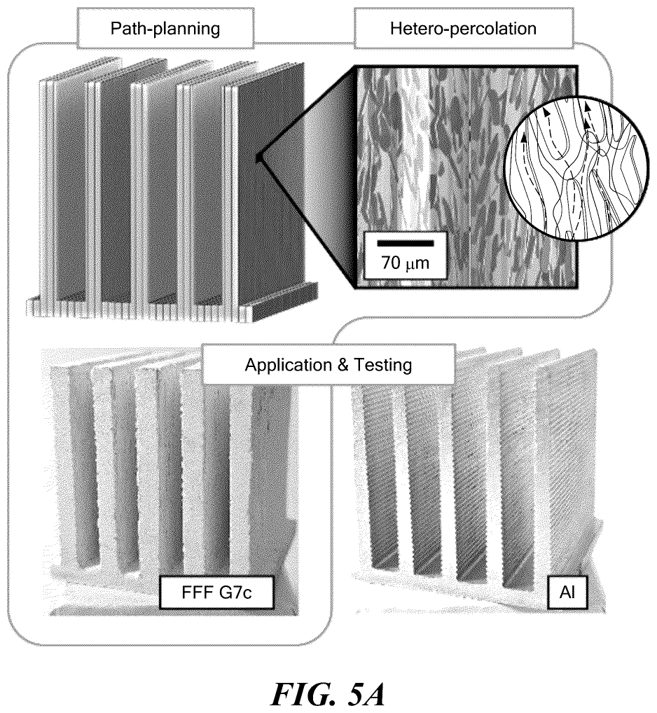

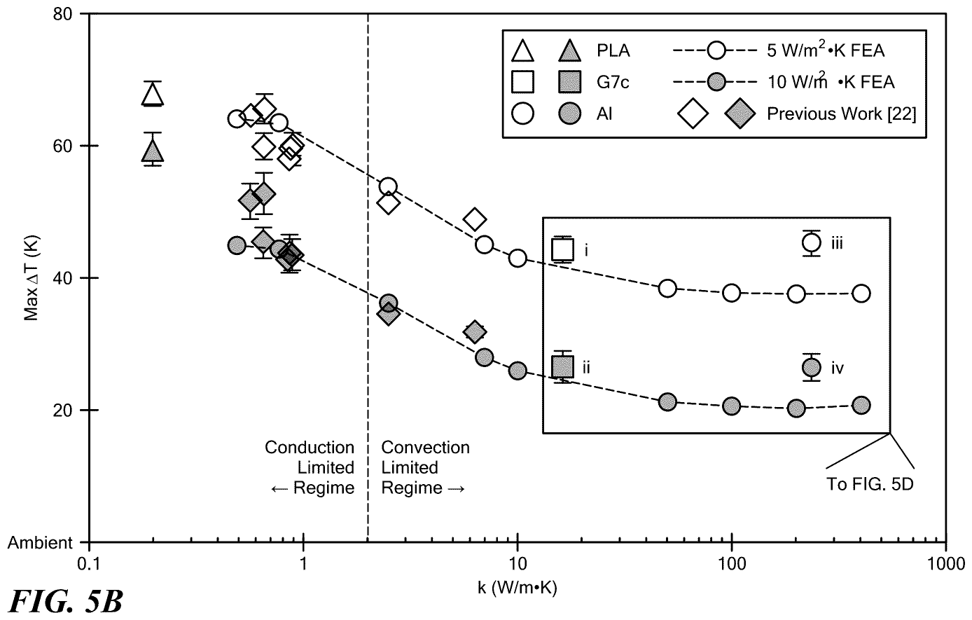

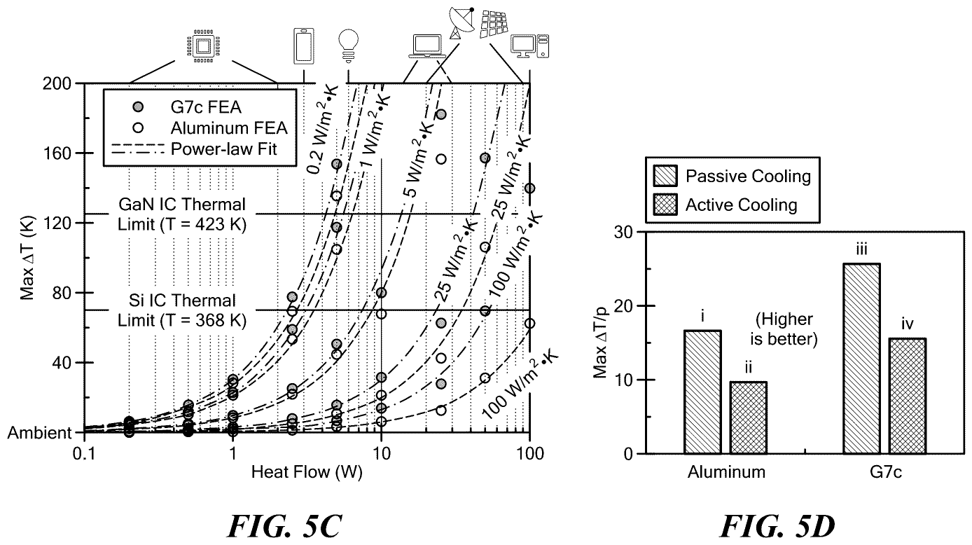

Composite variant G7c defined a success for each of the key design goals in this work and warranted application testing against incumbent materials solutions. A five-fin heatsink geometry was printed from G7c with all print paths aligned such that the TCPC strong-axis thermal conductivity was perpendicular to the base of the heatsink (FIG. 5A). As-printed and thermally post-processed G7c heatsinks were evaluated within a laminar flow enclosure by measuring the steady state temperature of a 5 W Peltier plate mounted to the base of the heatsink under passive (fan off) and active (fan on) airflow conditions. The G7c heatsink reduced peak temperatures to match the aluminum heatsink, highlighting G7c as a viable substitute for the metal heatsink under a 5 W load while offering low-loss dielectric properties (FIG. 5b). Further, the lower density of G7c compared to aluminum offers a density-normalized performance boost compared to the metal incumbent (FIG. 5b inset).

To further understand the performance of G7c, especially at higher wattages, a finite element analysis (FEA) was developed. The FEA models fit the experimental data well and allow for extrapolation across multiple device powers and convection coefficients (FIG. 5c). For thermal loads up to 10 W, G7c heatsinks are expected to perform comparable to aluminum with convection conditions of 5 W/m²·K and below. Furthermore, because the hBN TCPC can be additively manufactured, topologically and microstructurally optimized heatsinks with complex fin designs can be easily implemented, leading to further performance gains.

### Overview of Evolutionary Materials Design (G0-G7)

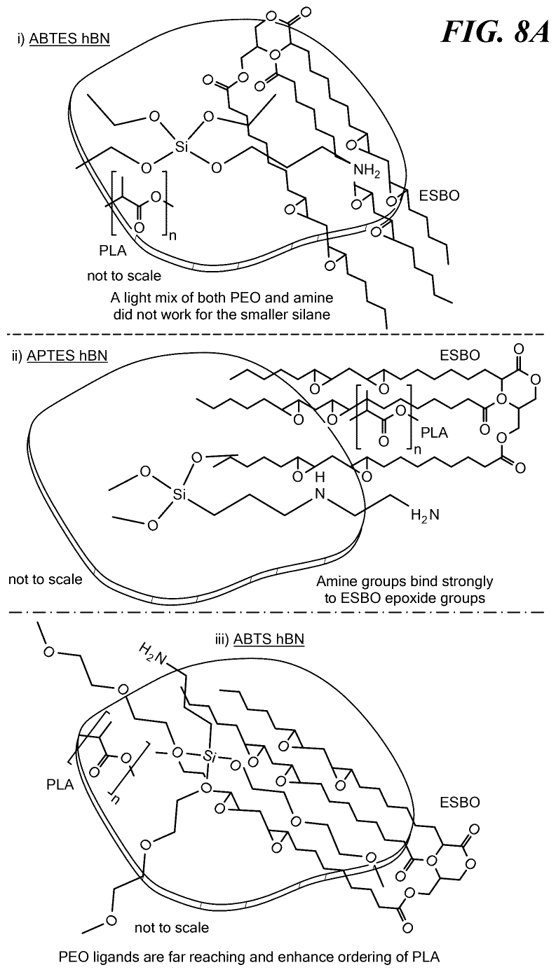

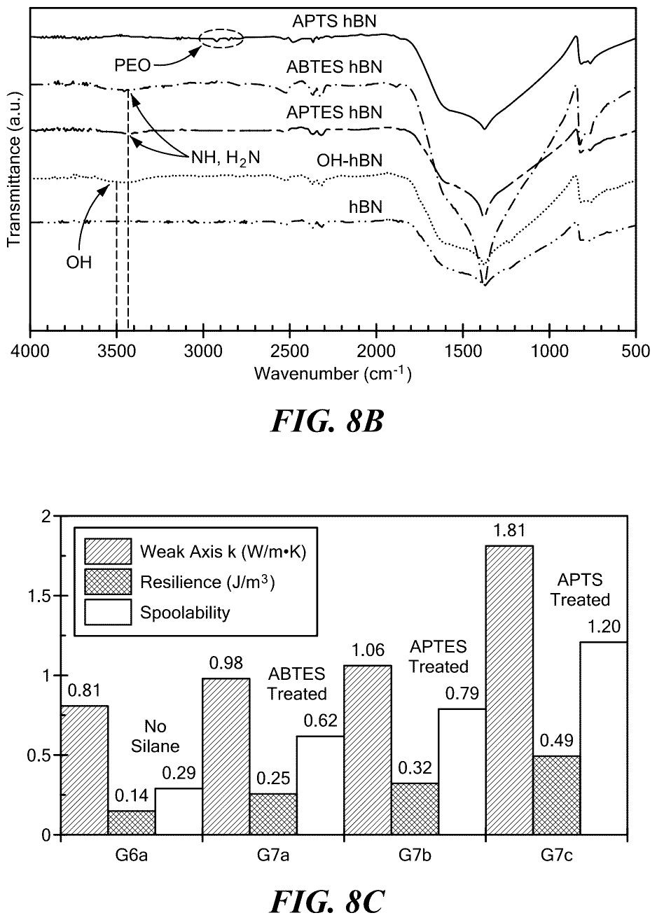

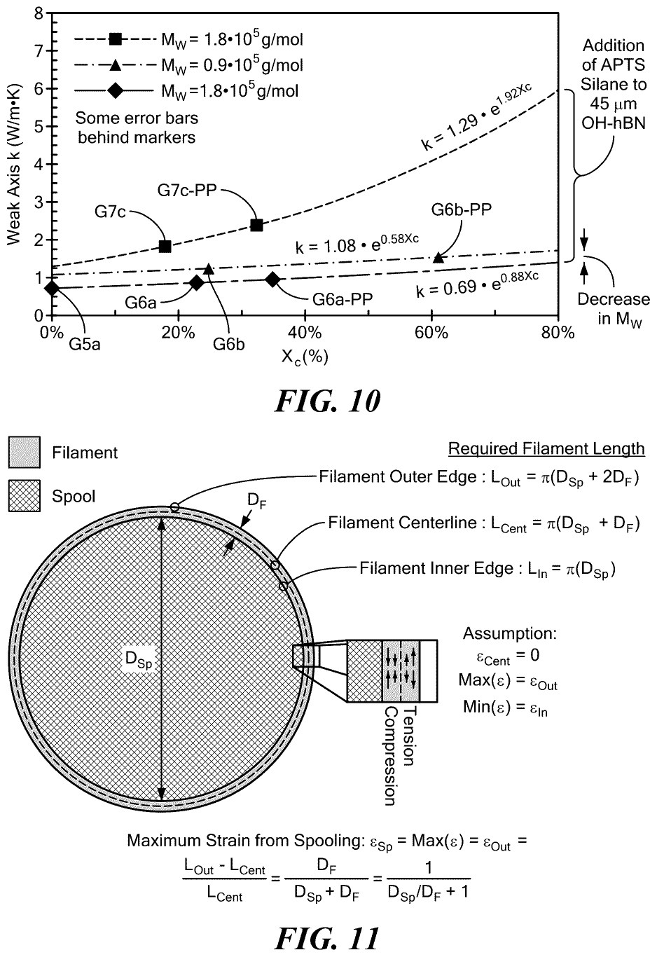

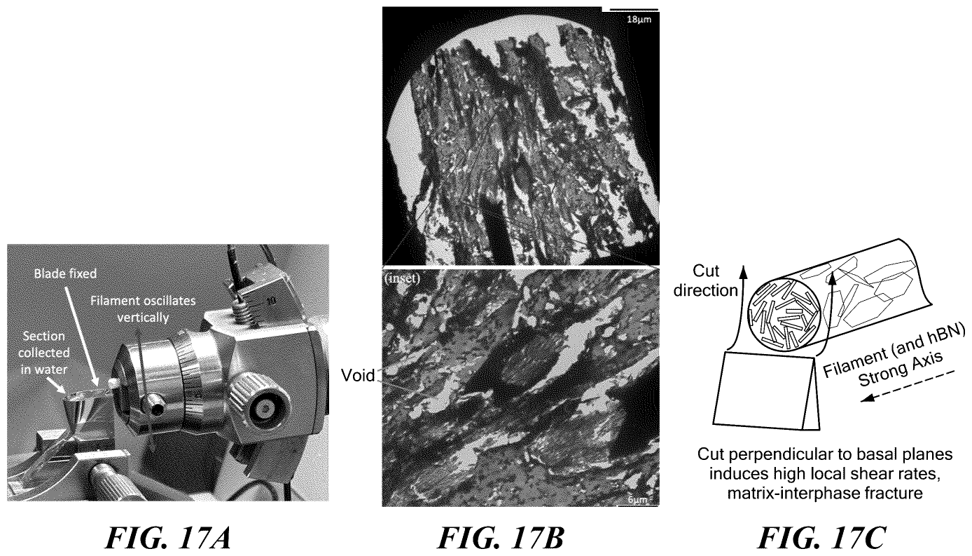

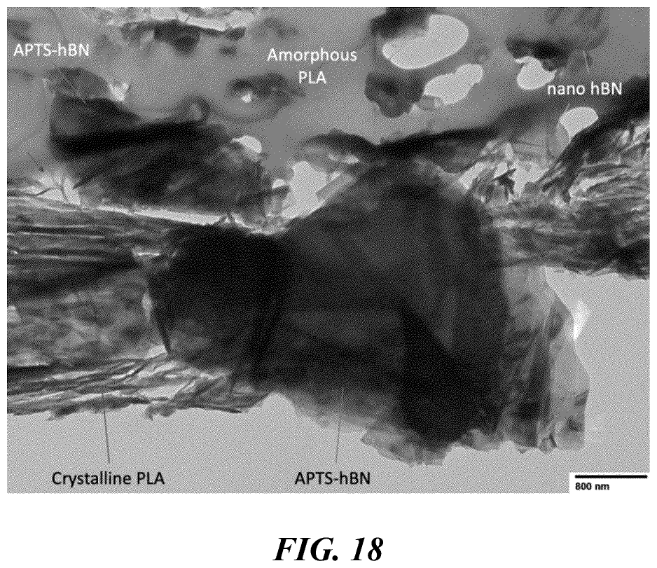

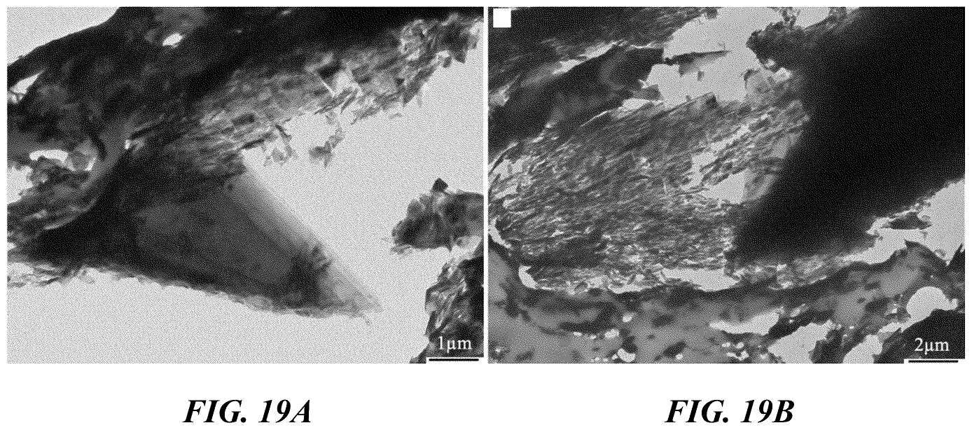

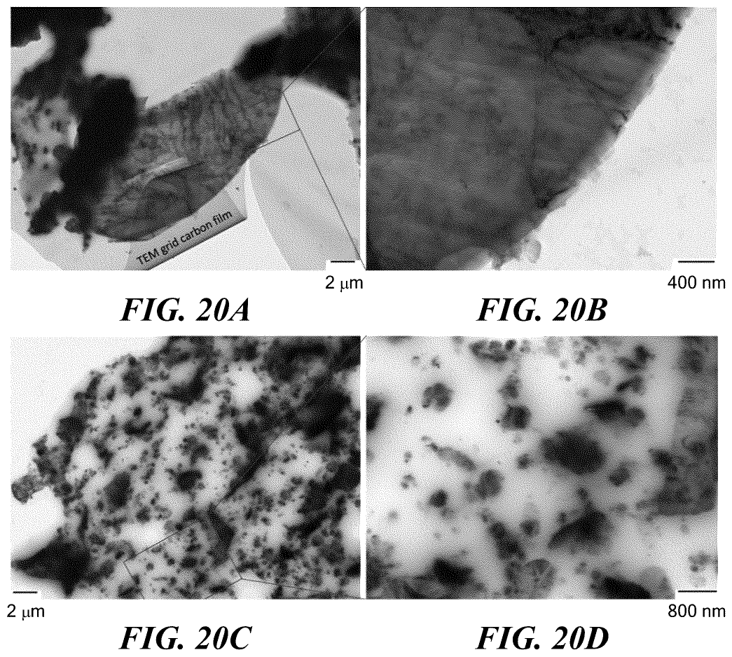

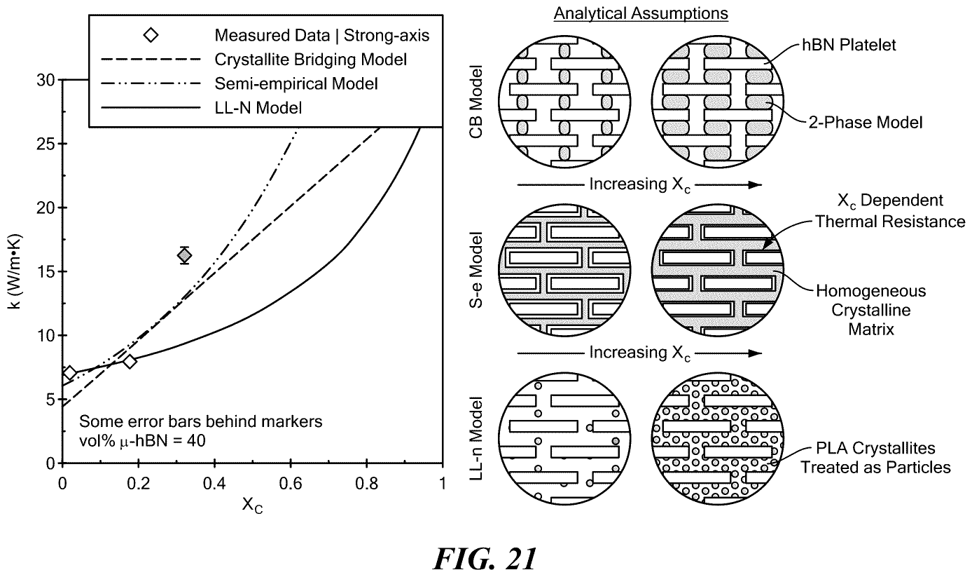

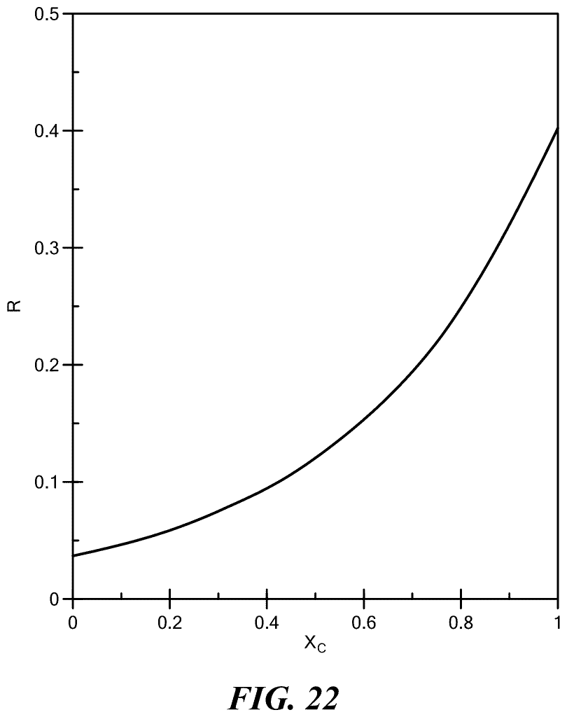

Through evolutionary design, seven generations of TP were investigated. Below in Table 3, all 23 composite variations are presented with relevant information on composition and morphology, followed by a brief overview of key results. In FIGS. 6A-61B the key performance changes are displayed with some graphical indicators of the goal effected by that change.

TABLE 4
All investigated TCPC generations.

| Generation | Polymer | Polymer | | Surface | |
|---|---|---|---|---|---|
| ID | Type | Morphology | Fillers | Chemistry | Additives |
| G0a/b/c/d | ABS | Proprietary | 20/30/40/ | As | None |
| | | | 50 vol % | received | |
| | | | 800 nm hBN | | |
| G1a/b/c/d | ABS | Proprietary | 20/30/40/ | As | None |
| | | | 50 vol % | received | |
| | | | 45 um hBN | | |
| G2a/b/c/d/e | PLA | Proprietary | 30/35/40/ | As | None |
| | | | 45/50 vol % | received | |
| | | | 45 um hBN | | |
| G3a | PLA | Non-crystalline | 45 vol % | As | None |
| | 4060D | M_{W} = 1.8 · 10⁵ | 45 um hBN | received | |
| | | g/mol | | | |
| G3b | PLA | Non-crystalline | 40 vol % | As | None |
| | 4060D | M_{W} = 1.8 · 10⁵ | 45 um hBN | received | |
| | | g/mol | 5 vol % | | |
| | | | 800 nm hBN | | |
| G4a/b | PLA | Non-crystalline | 40 vol % | As | 5/10 wt % ESBO |
| | 4060D | M_{W} = 1.8 · 10⁵ | 45 um hBN | received | 1 wt % AO 1010 |
| | | g/mol | 5 vol % | | |
| | | | 800 nm hBN | | |
| G5a | PLA | Non-crystalline | 40 vol % | OH | 10 wt % ESBO |
| | 4060D | M_{W} = 1.8 · 10⁵ | 45 um hBN | treatment | 1 wt % AO 1010 |
| | | g/mol | 5 vol % | | |
| | | | 800 nm hBN | | |
| G6a | PLA | Semi-crystalline | 40 vol % | OH | 10 wt % ESBO |
| | 2003D | M_{W} = 1.8 · 10⁵ | 45 um hBN | treatment | 1 wt % AO 1010 |
| | | g/mol | 5 vol % | | |
| | | | 800 nm hBN | | |
| G6b | PLA | Semi-crystalline | 40 vol % | OH | 10 wt % ESBO |
| | 3001D | M_{W} = 0.9 · 10⁵ | 45 um hBN | treatment | 1 wt % AO 1010 |
| | | g/mol | 5 vol % | | |
| | | | 800 nm hBN | | |
| G7a | PLA | Semi-crystalline | 40 vol % | OH | 10 wt % ESBO |
| | 2003D | M_{W} = 1.8 · 10⁵ | 45 um hBN | treatment + | 1 wt % AO 1010 |
| | | g/mol | 5 vol % | ABTES | |
| | | | 800 nm hBN | | |
| G7b | PLA | Semi-crystalline | 40 vol % | OH | 10 wt % ESBO |
| | 2003D | M_{W} = 1.8 · 10⁵ | 45 um hBN | treatment + | 1 wt % AO 1010 |
| | | g/mol | 5 vol % | APTES | |
| | | | 800 nm hBN | | |
| G7c | PLA | Semi-crystalline | 40 vol % | OH | 10 wt % ESBO |
| | 2003D | M_{W} = 1.8 · 10⁵ | 45 um hBN | treatment + | 1 wt % AO 1010 |
| | | g/mol | 5 vol % | APTS | |
| | | | 800 nm hBN | | |

FIGS. 6A-6B show the progression in thermal conductivity, spoolability, and resilience for all representative compositions. Initial formulations (G0a-d) used an ABS matrix with 800 nm hBN platelets at 20-50 vol %, resulting in weak-axis thermal conductivities up to 0.75 W/m·K (FIG. 6A). Generations G1a-d used larger 45 μm hBN platelets to reduce the number of hBN/ABS interfaces, achieving weak-axis thermal conductivities up to 1.55 W/m·K. G1c-d exhibited excessive melt viscosities and were difficult to extrude into filament and print. Switching to PLA in generations G2a-e improved processability due to PLA's lower melt viscosity. Increasing filler volume fractions increased thermal conductivities (FIG. 6A), with 45 vol % hBN (G2d) balancing thermal conductivity and processability. From G3a onward, a non-proprietary and fully characterized PLA chemistry was used (FIG. 6Bi). The G3b formulation, with a hybrid platelet size composition (FIG. 6Bii), consisting of 40 vol % 45 μm hBN and 5 vol % 800 nm hBN, improved both thermal conductivity and processability.

Adding epoxidized soybean oil (ESBO) in G4a-b (FIG. 6Biii,iv) improved spoolability, Consistent with prior findings that 10-20 wt % ESBO enhances PLA's strength and ductility. Adding 1 wt % antioxidant (AO 1010) minimized thermal degradation seen in prior generations as discoloration and shifts in Tg. Despite improved spoolability, both thermal conductivity and, surprisingly, resiliency were reduced.

Hydroxylation of hBN micro-platelet surfaces (G5a, FIG. 6Bv) enhanced hydrogen bonding with PLA and ESBO, improving both thermal conductivity and printability. This suggested surface functionalization as a key route to enhancing multiple performance metrics, and specifically provided a strong anchoring point for silane-based surface deposition.

Following G5a, polymer morphology was probed by testing various PLA grades: fully amorphous (4060D), semi-crystalline (2003D), and low molecular weight semi-crystalline (3001 D). Increased PLA crystallinity improved thermal conductivity (G6a-b, FIG. 6Bvi,vii), but the high-crystallinity 3001 D PLA was too brittle. Thus, 2003D was chosen for future generations.

Finally, three silane chemistries were tested: 4-aminobutyltriethoxysilane (ABTES, G7a, FIG. 6Bviii), n-(2-aminoethyl)-3-aminopropyltrimethoxysilane (APTES, G7b, FIG. 6Bix), and 3-aminopropyltris(methoxyethoxyethoxy)silane (APTS, G7c, FIG. 6Bx). These silanes were selected for their amine groups, which interact well with epoxide groups in EBSO, and their polyethylene oxide oligomers, known to increase PLA crystallinity. APTS significantly improved thermal conductivity due to silane-mediated crystal templating.

Across seven compositional generations (23 composite recipes in total), nano-micro-, and meso-scale tuning was used to produce dielectric polymer composites with emergent thermally conductive properties and mechanical properties amenable for processing via FFF. A small amount of nano-filler was found to go a long way. The addition of just 5 vol % 800 nm hBN to the 40 vol % 45 μm hBN improved the composite thermal conductivity by ˜16%. The addition of toughening plasticizer, antioxidant, and the hydroxylation of the micro-hBN increased overall mechanical properties and FFF processability of the resultant composites. The crystallizable content of the polymer matrix was used to increase the composite thermal conductivity. Selected silanes were used to increase the phononic transfer between micro-platelets to enhance the thermal conductivity of the designer-hBN-PLA composite to 1.81±0.11 W/mK, weak axis. Furthermore, two of these composites were proven to be FFF processable with one of the composite generations being able to be spooled around standard 200 mm FFF filament reals. The high aspect ratio of the hBN platelet filler was taken advantage of through the shear alignment induced along the FFF print bead direction. After printing, the shear aligned and highly percolated hBN phononic ‘highways’ within each print bead resulted in a TCPC with a strong axis thermal conductivity of 7.97±0.26 W/mK. This high thermal conductivity was increased to 16.27±0.42 W/mK (a metric that beats popular additive metal feed stocks) by a thermal post process to increase percent crystallinity within the polymer matrix. Heatsinks printed out of this TCPC were shown to perform on the same level as an aluminum heatsink under both passive and active cooling scenarios. The TCPCs described herein are suitable for use in emergent high performance and energy dense electronic devices.

### EXAMPLES

### Example 1. Materials and General Methods

### Materials

45 μm hBN platelets were procured from Momentive Quartz Technologies Inc. (Strongsville, OH, USA). 800 nm hBN platelets were procured from US Research Nanomaterials, Inc. (Houston, TX, USA). Each hBN platelet had a high aspect ratio; the platelet thicknesses were confirmed with cross-sectional micrographs to be 1.5±0.5 μm for the 45 μm hBN and 40 nm for the 800 nm hBN. All Ingeo™ Biopolymer PLA variants were purchased from NatureWorks (Plymouth, MN, USA). The three PLAs were: 4060D, an amorphous polymer, 2003D, and 3001 D, two semi-crystalline polymers. Epoxidized soybean oil plasticizer (ESBO, CAS #: 91722-14-4), polymer antioxidant pentaerythritol tetrakis(3,5-di-tert-butyl-4-hydroxyhydrocinnamate) (Antioxidant 1010, CAS #: 6683-19-8), Chloroform (CAS #: 67-66-3), and NaOH pellets (ACS reagent grade, CAS #: 1310-73-2) were bought from Sigma-Aldrich (Saint Louis, MO, USA). The following three silanes were purchased from Gelest, Inc. (Morrisville, PA, USA): 3-aminopropyltris(methoxyethoxyethoxy)silane (APTS, CAS #: 87994-64-7), n-(2-aminoethyl)-3-aminopropyltrimethoxysilane (APTES, CAS #: 1760-24-3), and 4-aminobutyltriethoxysilane (ABTES, CAS #: 3069-30-5).

### Differential Scanning Calorimetry (DSC)

Differential scanning calorimetry was performed with a TA Instruments Q2000 DSC at heating/cooling rates of 1, 10, and 20° C./min between 22° C. and 200° C. DSC was performed to record the changes in crystallinity, glass transition temperature (Tg), crystallization temperature (T_{c}), and melt temperature (Tₘ). A baseline protocol of the following steps was used to assess the as-received PLA variants and the composites after solvent casting and filament extrusion: (1) Ramp 10° C./min to 200° C., (2) Isotherm for 5 min, (3) Ramp −20° C./min to 22° C., (4) Ramp 10° C./min to 200° C., (5) Ramp −1° C./min to 22° C., (6) Ramp 10° C./min to 200° C., (7) Ramp 10° C./min to 22° C. All other DSC runs were a ramp at 10° C./min to 200° C. to assess the material's characteristics after printing. Percent crystallinity, X_{c}, was calculated based on Equation 1 below, where enthalpy at 100% crystallinity, ΔH_{f}, for PLA is 93 J/g, and w is for the weight fraction of polymer in the respective composite filaments.

$${X}_{c} = \frac{Δ {H}_{m} - Δ {H}_{c c}}{Δ {H}_{f} \cdot w} . \qquad ( 1 )$$

### Scanning Electron Microscopy (SEM)

Micrographs were obtained from a Hitachi S-4800 scanning electron microscope. Micrographs of samples were collected from polished cross-sections of each composite filament to investigate the physical differences in the particle-matrix interphase between each composite variant.

### Energy Dispersive X-Ray (EDX) Spectroscopy

An Ametek, Inc. EDAX Element EDS System (Warrendale, PA, USA) was used with the Hitachi S-4800 SEM to confirm the elemental components present when observing the surfaces of neat and surface treated hBN platelets.

### Fourier Transform Infrared (FTIR) Spectroscopy

A Jasco FT/IR-6600 spectrometer was used to measure the spectroscopy of the hBN platelets before and after various surface treatment procedures to confirm success of the treatment process via the KBr window method. 0.004 mg of micro-platelet hBN (0.0002 mg nano-platelet) were pestled with 0.5 mg of KBr to a homogenous fine powder. 0.04 mg were compressed at 30 MPa into a 6 mm transparent sample disk for 60 seconds. All spectrographs were measured against a KBr baseline.

### Gel Permeation Chromatography (GPC)

An Agilent Technologies Agilent 1260 Infinity GPC with two Agilent PC gel 5 μm Mixed D columns and refractive index and multi-angel light scattering detectors was used to determine the molecular weights of the three NatureWorks PLAs received. Each sample was dissolved in tetrahydrofuran (THF) and diluted to the appropriate concentration. Injected sample solutions were between 1.5 g/mL and 2.0 g/mL solutions of THF. Samples were then microfiltered into appropriate vial before GPC injection. Retention time of PLA samples was approximately 10-minutes during a 30-minute total run time. The molecular weights of the samples were compared to a standard polystyrene calibration curve. Samples were run a minimum of three times.

### Thermal Interface Measurement (TIM)

An Analysis Tech Thermal Interface Measurement Tester was used to characterize the thermal conductivity of the various composite recipes. The bottom plate of the TIM tester was actively cooled to a set point of 18° C., while the top plate was set to raise in temperature to maintain the middle of the sample disk at a desired temperature of 50° C. High viscosity Dow Corning 200 silicone oil (Sigma-Aldrich, CAS #: 63148-62-9) was used as an interface fluid to ensure an even and full contact with both TIM surfaces. The contact pressure was set to 100 kPa. Sample sets of 33 mm diameter disks of at least three different thicknesses were run to determine the thermal conductivity of the samples. All the composite generations within this work were tested as fully dense hot-rolled disks to measure their respective through-plane conductivities without the inherent effects of FFF. Generations of interest were printed via FFF into disks with either the print beads orthogonal to or parallel to the TIM testing direction to determine the through- and in-plane conductivity, respectively.

### Application Testing of FFF TCPC

A five-fin heatsink was printed out of two variants of the printable composite generations and was tested using the heatsink testing set up diagramed in Error! Reference source not found. 23. The setup is a benchtop wind tunnel that can flow laminar air across a heatsink that is affixed to the heating side of a TEC1-12706 12V 6A Peltier plate (HiLetgo, China). K-type thermocouples (Omega, Norwalk, CT, USA) are embedded between the heatsink and the Peltier heating element to track local temperature. To test a heatsink, the following protocol was followed: (i) the heatsink was affixed to the Peltier heating element using PK-3 Thermal Compound (Prolimatech Inc., Taiwan) and a mounting bracket; (ii) the benchtop wind tunnel was closed and allowed to equilibrate at ambient (˜25° C.) for 1 minute; (iii) the Peltier heating element was then fully powered at 5V and held on until the temperature saturated; (iv) the fan was then turned on to apply active convection—and the temperature decrease was monitored until the system reached steady-state; (v) finally, the heat source was powered off and the temperature was monitored until the fan cooled the system back down to ambient. The heatsinks were printed such that the print beads would be parallel to the heat source. A test with an aluminum heatsink of the same dimensions was also run for comparison.

### Example 2. TCPC Creation with PLA and hBN

Each composite variant within this work was created with a hBN platelet volume percentage of 45 vol % in a PLA matrix. The following method describes the process of creating a variant with both nano and micro platelets and a complex matrix composition. This process remained the same for other generations, sub surface treated platelets or different amounts of polymer additives and different base PLAs.

A total of 45 vol % hBN was added to a polypropylene speedmixing cup (Flacktek Inc., Landrum, SC, USA), where 5 vol % was 800 nm hBN and 40 vol % was 45 μm hBN. The remaining 55 vol % was the polymer matrix: PLA, 10 wt % to PLA ESBO, 1 wt % to PLA Antioxidant 1010. To the cup with all its constituents, 84 vol % chloroform was added to dissolve the PLA. The speedmixing cup's threads were wrapped with polytetrafluoroethylene tape before screwing the cap on to prevent evaporation and leakage of the chloroform during the solvation of the PLA matrix and during later mixing steps. After 8 hours, the PLA is fully dissolved within the chloroform. The sealed speedmixing cup was then speedmixed at 2600-RPM for 2 minutes in a DAC 150.1 FVZ-K SpeedMixer. The resulting homogenous suspension of hBN platelets within a PLA solution was pour out evenly onto a tray lined with aluminum foil. This tray was then placed in a 60° C. drying oven within a fume hood and let to dry for at least 8 hours, or until the chloroform was completely evaporated. Once dried and cooled, the composite sheet was peeled away from the aluminum foil and broken into flakes for later filament extrusion and hot-rolling methods.

### Example 3. Surface Modification of hBN Platelets

Two surface modification procedures were performed on the hBN platelets—a NaOH hydroxylation treatment and a silane hydrolysis silanization treatment.

The hydroxylation procedure was as follows. NaOH pellets were dissolved in deionized water (DI) at a 1:100 weight ratio in an Erlenmeyer flask. On a 90° C. stir plate, a magnetic stir bar was used to mix the NaOH ion solution at 500-RPM. At a 1:30 weight ratio, untreated hBN micro-platelets (1:300 wt ratio if nano-platelets) were added to the stirring mixture. The stir bar RPM was increased to 800-RPM and the flask was wrapped in aluminum foil to maintain even heating and the top was covered with aluminum foil to limit evaporation of the solution. This suspension was mixed for 4.5 hours. After mixing, the platelets were then vacuum filtered out of suspension. The freshly treated platelets were rinsed three times with DI and three more times with isopropyl alcohol. After which, the platelets were dried at 60° C. in an oven overnight.

The silanization procedure was as follows. Silane was solutionized into 90° C. DI at a 1:999 weight ratio in a polypropylene Erlenmeyer flask. This solution was stirred by a magnetic stir bar at 500-RPM. At a 1:20 weight ratio, untreated hBN micro-platelets (1:200 wt ratio if nano-platelets) were added to the stirring mixture. The flask was wrapped in aluminum foil to maintain even heating and the top was left un-covered to allow for steady evaporation. The hydrolysis reaction was run for 24 hours. After mixing, the platelets were then vacuum filtered out of suspension. The freshly treated platelets were rinsed three times with DI and three more times with isopropyl alcohol. After which, the platelets were dried at 60° C. in an oven overnight.

### Example 4. Filament Extrusion of TCPCs

A modified Noztek Pro single screw extruder (Shoreham, West Sussex, UK) was used to extrude each composite variant into FFF filament. The modifications made to the stock extruder were the additions of a second temperature controller for the two the resistive heating collars and a speed controller for the screw motor. Each composite variant was extruded with these settings to produced consistent filament diameters and surface finishes: 170° C. initial heating zone, 150-190° C. second heating zone, 100% screw motor speed. A 2.77 mm diameter bored nozzle was used to extrude the resultant filaments. Depending on the composite variant, the extruded filament ranged from 2.65-2.85 mm in diameter.

### Example 5. FFF Processing of Novel TCPC

A LulzBot TAZ6 FFF machine with a stainless steel 1.2 mm nozzle from Micro Swiss was used to print all samples. Selected print parameters were as follows: 1.2 mm line width, 210° C. extruder temperature, 65° C. bed temperature, 30 mm/s print speed, 2 outer shells, and −45/45° infill raster (unless otherwise specified). A coating of polyvinyl alcohol (PVA) glue was required to achieve good bed adhesion to complete the prints successfully. All gcode to print each sample was generated using Simplify3D. For two composite generations, the feed gear assembly had to be altered. Further due to the high thermal conductivity of these composites, the stock extruder cooling fan had to be replaced.

### Example 6. Three-Point Bend Testing of TCPC Filaments

An Instron 5948 load frame with a 2 kN load cell was used to perform all mechanical tests. 3-point bend tests were performed in accordance with ASTM D790-17 at a strain rate of 0.1 mm/mm/min. The Instron software, BlueHill 3, recorded all data from the mechanical tests. Flexural modulus (E_{f}), flexural strength (σ_{f}), strain at break (ε_{b}), and resilience were all properties determined from this test. Each composite filament was tested at least n=5. Resilience (J/m³) was integrated from the start of test to the yield or the break of the filament sample (whichever happened first). A metric for filament “spoolability” was calculated from the ratio of ε_{b} to the calculated max strain (εₘₐₓ) of a 2.85 mm diameter filament (D_{f}) being spooled around a 200 mm diameter spool (Dₛ) (Equation 2).

$$S p = {ε}_{b} / {ε}_{S p} = {ε}_{b} [ ( {D}_{S p} / {D}_{F} + 1 ) ]$$

### Example 7. Creation of TIM Disks for Measuring Weak & Strong Axis Thermal Conductivity of Printed Parts

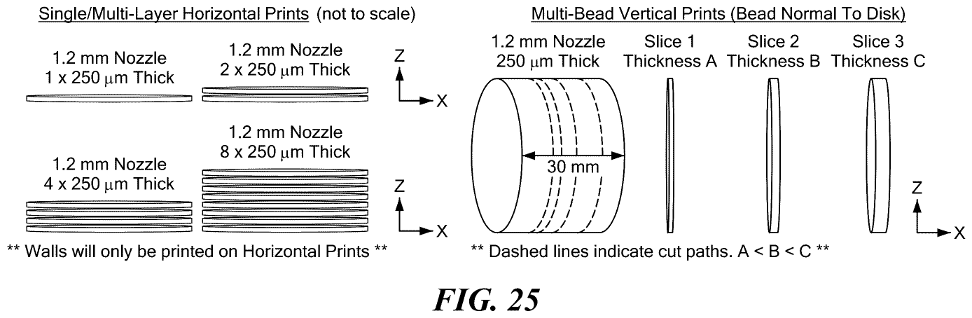

The array of print samples for TIM testing are visualized below in FIG. 25. A set of four 33 mm disks with thickness of 0.25, 0.5, 1, and 2 mm were printed horizontally to the print bed. These “H-prints” were designed such that TIM testing would determine the through-plane conductivity of the printed parts (weak axis). This is the thermal conductivity that includes all inter-layer resistances between each print layer and would be the “weakest” phonon transfer direction. A 33 mm diameter, 30 mm long cylinder was printed horizontally to the print bed with all the print beads oriented along the length of the cylinder (strong axis). The cylinder was then cut into three disks of varying thicknesses. These “V-prints” were designed such that no inter-layer resistances would be included in the measured thermal conductivity. It was assumed that the intra-layer resistances within each V-print layer would be negligible, since they were parallel to the TIM testing direction. The thermal conductivity measured from these samples was in the “strongest” phononic transfer direction, strong axis thermal conductivity, and would be the highest conduction values for the composites. These V-print strong axis samples required a great volume of composite to first optimize print parameters and then complete a print for sample creation and testing. Therefore, the creation and testing of such samples was limited to the best composite variants uncovered in this work.

### Example 8. DSC of Neat PLA Variants

The thermo-phasic characteristics of each PLA variant are tabulated below in Table 5. 2003D had no cold crystallization even during as heat up after a ‘fast’ cool of −20° C./min. For a semi-crystalline polymer, on its on 2003D was not very crystalline and was only able to reach a X_{c}=2.6% after a slow cool of −1° C./min. 3001 D, on the other hand, had a clear cold crystallization temperature and was able to be crystallized to a X_{c}=20.8% after a ‘slow’ cool of −1° C./min (Table 5).

TABLE 5
DSC results for as-received PLA pellets.

| | | T_{g} | T_{c} | Tₘ | X_{c} (%) | X_{c} (%) |
|---|---|---|---|---|---|---|
| PLA | M_{w} (g/mol) | (° C.) | (° C.) | (° C.) | after −20° C./min | after −1° C./min |
| 4060D | 181,600 ± 5300 | 60 ± 2 | — | — | 0 | 0 |
| 2003D | 183,850 ± 1000 | 62 ± 1 | — | 150 ± 2 | 1.5 | 2.6 |
| 3001D | 85,801 ± 1500 | 65 ± 4 | 136 ± 2 | 168 ± 1 | 2.2 | 20.8 |

Adding the mix of micro and nano-platelets to the two new PLA variants altered their thermo-phasic responses recorded in DSC (see Table 1). For each new generation of composite, the baseline DSC protocol was run on the ‘Fresh’ recently solvent cast composite and the composite after extruding into filament. G6a had a 2003D PLA matrix, adding the hBN platelets had minimal effect on the thermal characteristics of the base polymer; however, the platelets did alter the crystallinity of the polymer matrix. Most notable in the DSC of the G6a filament, a T_{c} was now apparent at 114±8° C. and the percent crystallinities after the fast and slow cool were both very different from their neat 2003D counterpart: 0.2% and 26.9%, respectively. This increase in crystallinity also occurred within G6b which had the 3001 D PLA as its matrix. G6b filament recorded a notable change to some of the 3001 D thermo phasic properties as well as crystallinity content: G6b glass transition temp reduced to 51±1° C., the crystallization temperature reduced to 108±17° C., the fast cool crystallinity was 43.4%, and the slow cool X_{c}=41.7%. The volume taken up by these platelets reduced the overall volume each polymer chain could occupy and further induced order amongst the polymer chains, especially after the composites were extruded into filament. As filament, the filler OH-hBN was shear aligned along the length of the extrudate and the volume between each platelet was decreased greatly as the platelets became more percolated.

### Example 9. LulzBot TAZ6 FFF Printer Modifications

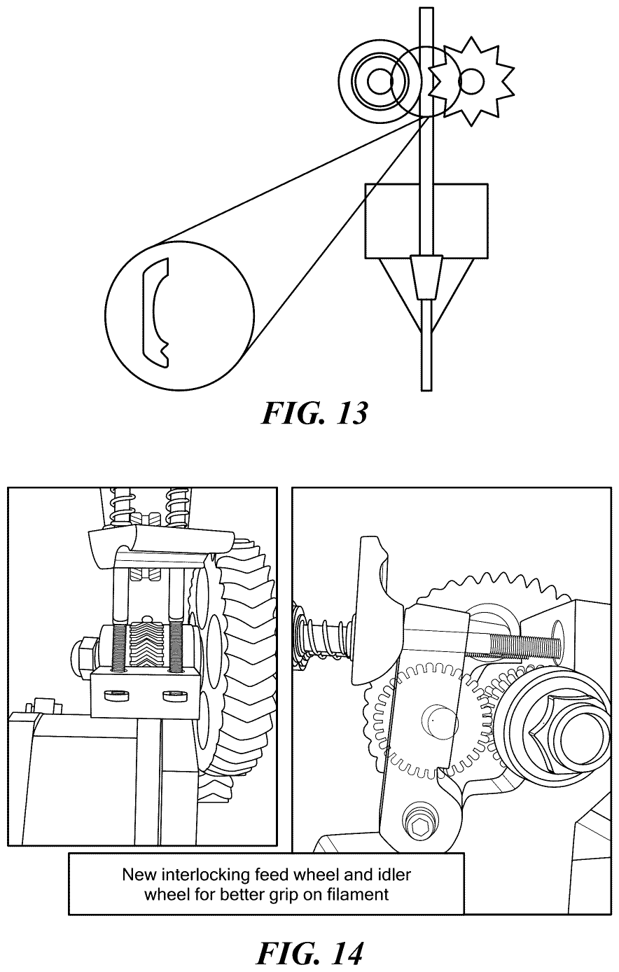

The extruder assembly that comes with the LulzBot TAZ6 FFF Printer uses a steel hob gear to grip into filament to push it down into the heated chamber for melting and subsequent extrusion. The G5a composite was still relatively brittle and would regularly get chewed out by the hob gear feeding mechanism (FIG. 13).

To avoid filament chew-out, the feeding assembly was altered to accommodate a set of 24 mm diameter TPU interlocking hob gears. They were designed such that the gear's outer teeth would interact when the two rubber gears were pressed around the filament (FIG. 14). This assembly proved to have an extremely strong grip on the G5a and later G7c composite variants.

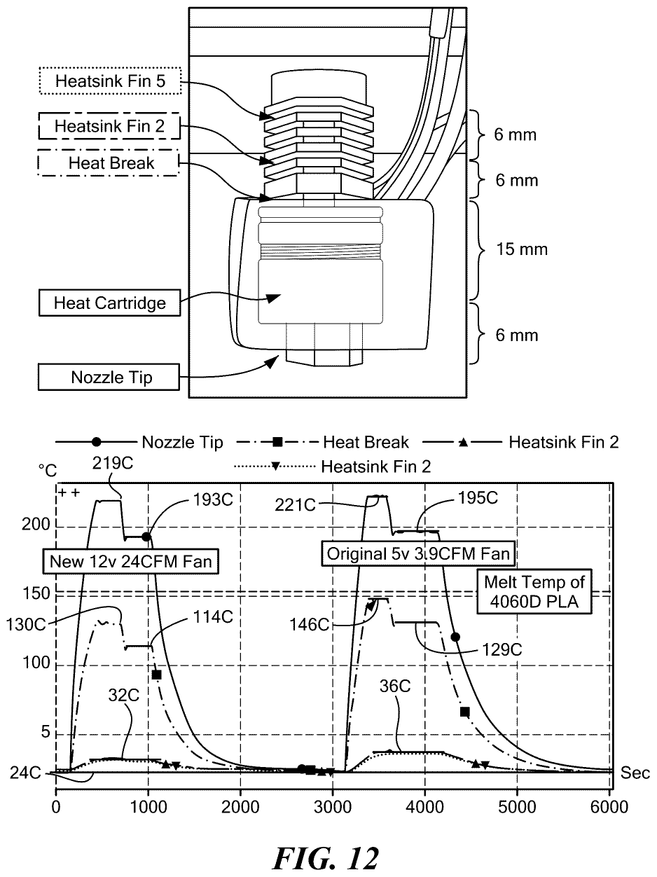

During successive print sessions the extruder assembly would regularly clog. This issue was determined to be caused by the high thermal conductivity of the TCPCs. The TAZ6 extruder assembly has the incoming filament travel through a “heat-break”, heater block, and then finally out the print nozzle during extrusion. The temperature transition from the heat-break to the heater block must be stark and average well below the melt temp of the incoming filament. Otherwise, the filament will soften too far up the feed tube and clog the process—heat creep. The high thermal conductivity of the G5a and G7c TCPCs easily conducted heat way from the heater block up to the heat-break. To amend this issue and prevent future heat-creep, a new more powerful cooling fan was added to the heat-break portion of the printhead assembly. With the original TAZ6 heat-break fan, the temperature at the heat break reached 146° C. Just 4° C. away from the melt temp of 4060D PLA (the G5a polymer matrix). The more powerful heat-break fan was able to maintain the heat-break temperature well below the melting point of the TCPC (FIG. 12).

### Example 10. Annealing of Composite Variant G5a

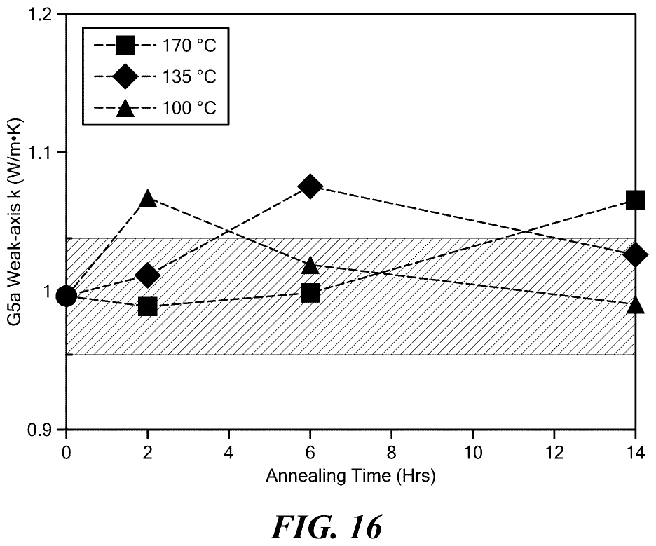

Annealing composite variant G5a at varying temperatures for different time lengths yielded little to no improvements in weak axis thermal conductivity compared to the as-printed values (FIG. 16). These data suggest that the high thermal conductivity of the composite results in a reduced thermal resistance at expected FFF interfaces. The increased thermal conductivity would lead to higher overall part temperatures as new layers are extruded out of the heated nozzle. Meaning that the part would stay at a temperature necessary to weld each layer and print bead to each other more strongly.

### Example 11. DSC Procedure to Determine Best Case Annealing Conditions for G7c

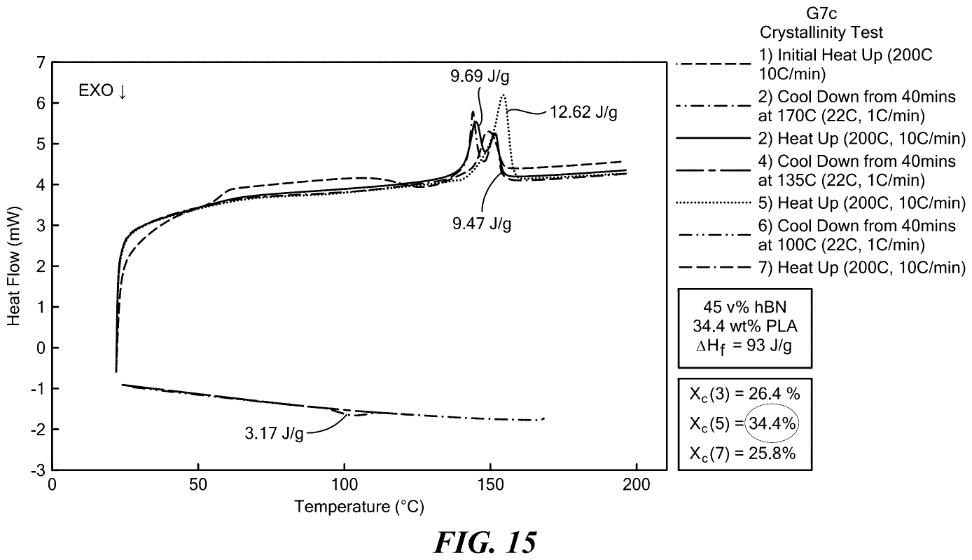

A DSC procedure was designed to fully melt and cool the G7c composite prior to each ramp to the respective anneal temperature to ensure the composite had an identical thermal history each time it was annealed (FIG. 15). Once the sample reached the annealing temperature, the sample was held under isotherm for 40 minutes to allow enough time for the composite matrix to fully crystallize. The full DSC procedure was as follows: (1) Ramp 10.00° C./min to 200.00° C., (2) Isothermal for 5.00 min, (3) Ramp 10.00° C./min to 22.00° C., (4) Equilibrate at 170.00° C., (5) Isothermal for 40.00 min, (6) Ramp 1.00° C./min to 22.00° C., (7) Ramp 10.00° C./min to 200.00° C., (8) Isothermal for 5.00 min, (9) Ramp 10.00° C./min to 22.00° C., (10) Equilibrate at 135.00° C., (11) Isothermal for 40.00 min, (12) Ramp 1.00° C./min to 22.00° C., (13) Ramp 10.00° C./min to 200.00° C., (14) Isothermal for 5.00 min, (15) Ramp 10.00° C./min to 22.00° C., (16) Equilibrate at 100.00° C., (17) Isothermal for 40.00 min, (18) Ramp 1.00° C./min to 22.00° C., (19) Ramp 10.00° C./min to 200.00° C.

### Example 12. G7c Filament Quality Considerations

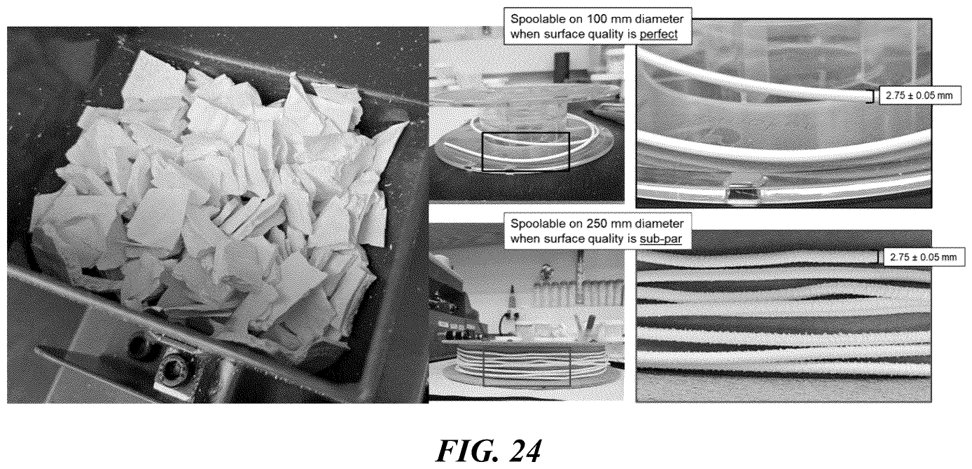

There was a very strong dependence of the G7c composite variant's spoolability on the filament surface finish (Table 6, FIG. 24). The surface finish was dependent on the filament extruder nozzle and melt/mixing zone temperatures. The best results seem to be from when the mixing zone (first hot zone) was at 170° C., the melt zone (second hot zone) was at 160° C., and the nozzle was around 130° C. The filament extruder used herein was limited in its capabilities to control all three of these key temperatures. The irregular flow rate caused by their variably sized solvent cast composite flakes further complicated the quality of the resultant filament.

TABLE 6
G7c filament surface quality played a critical
role in the filament's abilities to be spooled.

| G7c | | |
|---|---|---|
| Filament | Resilience | |
| Quality | (J/m³) | Spoolability |
| Good | 0.58 ± 0.08 | 1.50 ± 0.14 |
| Poor | 0.41 ± 0.09 | 0.95 ± 0.15 |

### Example 13. Design and Implementation of Heatsink Testing

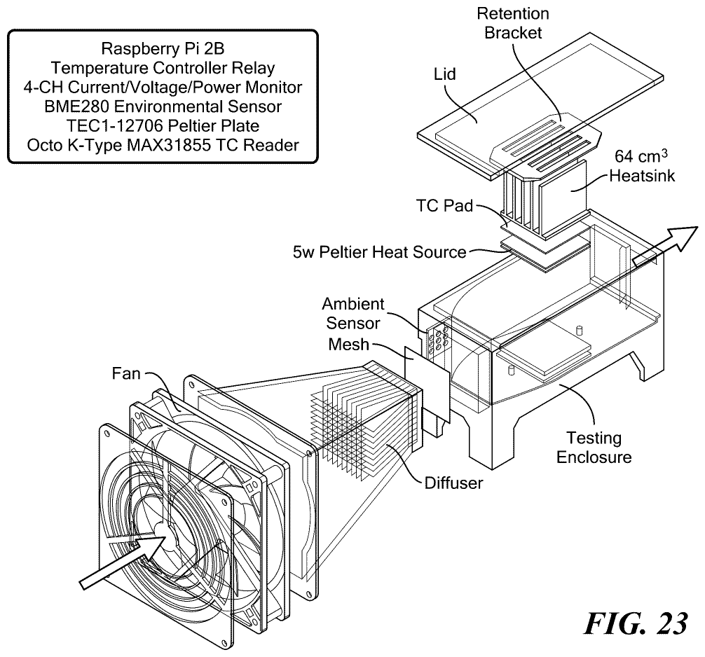

The heatsink tester used herein is diagrammed in FIG. 23, was controlled by a Raspberry Pi 2B (“RPi”). Connected to the RPi were the following: Robogaia Temperature Controller Relay, Waveshare 4-CH Current/Voltage/Power Monitor HAT, Waveshare BME280 Environmental Sensor, and Neem Tech Octo K-Type MAX31855 Thermocouple Breakout Board. The Robogaia relay was programed to turn on and off the HiLetgo TEC1-12706 40×40 mm Peltier plate heat source and the Noctua NF-A12×25 5V 120 mm fan. The thermocouple breakout board was used to measure the temperature from the embedded thermocouple pad between the bottom of the heatsink sample and the heat source. The environmental sensor was mounted to the outside of the heatsink testing chamber and was used to measure ambient temperature, humidity, and air pressure. The enclosure and diffuser were printed via FFF out of IC3D 2.85 mm Natural PETG filament. The diffuser was designed to take in the forced air from the 120 mm fan and funnel the flow into a near laminar flow prior to hitting the heatsink chamber. An aluminum mesh with 1 mm perforations was used to further ensure the directionality and diffusion of the air flow from the fan.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### REFERENCES

ADDIN EN.REFLIST [1] G. Ghaisas and S. Krishnan, “A Critical Review and Perspective on Thermal Management of Power Electronics Modules for Inverters and Converters,” Transactions of the Indian National Academy of Engineering, vol. 7, 09/24 2021, doi: 10.1007/s41403-021-00268-1.
[2] H. Nam, J. Kim, J. Jeon, H. Jhon, and J. Kim, “High-Performance RF Power Amplifier Module Using Optimum Chip-Level Packaging Structure,” IEEE Transactions on Industrial Electronics, vol. 69, no. 6, pp. 5660-5668, 2022, doi: 10.1109/tie.2021.3088328.
[3] M. A. Vadivelu, C. R. Kumar, and G. M. Joshi, “Polymer composites for thermal management: a review,” Composite Interfaces, vol. 23, no. 9, pp. 847-872, 2016/11/21 2016, doi: 10.1080/09276440.2016.1176853.
[4] P. Engineering. “Material Selection Charts.” www.proxom.net/material-selection/(accessed.
[5] A. L. Moore and L. Shi, “Emerging challenges and materials for thermal management of electronics,” (in English), Materials Today, vol. 17, no. 4, pp. 163-174, May 2014, doi: 10.1016/j.mattod.2014.04.003.
[6] Z. He, Y. Yan, and Z. Zhang, “Thermal management and temperature uniformity enhancement of electronic devices by micro heat sinks: A review,” Energy, vol. 216, p. 119223, 2021/02/01/2021, doi: doi.org/10.1016/j.energy.2020.119223.
[7] J. Kim, J. Oh, and H. Lee, “Review on battery thermal management system for electric vehicles,” Applied Thermal Engineering, vol. 149, pp. 192-212, 2019/02/25/2019, doi: doi.org/10.1016/j.applthermaleng.2018.12.020.
[8] M. T. Barako, V. Gambin, and J. Tice, “Integrated nanomaterials for extreme thermal management: a perspective for aerospace applications,” Nanotechnology, vol. 29, no. 15, p. 154003, 2018, doi: 10.1088/1361-6528/aaabe1.
[9] IPIECA. “Heat Exchangers.” www.ipieca.org/resources/energy-efficiency-solutions/efficient-use-of-heat/heat-exchangers/#reference-3 (accessed.
[10] N. T. Solutions. “How Do Cold Plates Work?” norenthermal.com/blog/2017/05/cold-plates-work/?lang=en (accessed.
[11] S. Electronics. “Heat Sink.” www.sunpower-uk.com/glossary/what-is-a-heat-sink/(accessed.
[12] I. Robert McKeown Company. “Thermal Management Solutions.” robertmckeown.com/thermal-management-solutions/ (accessed 2022).
[13] K. Grochalski et al., “The Influence of Geometry, Surface Texture, and Cooling Method on the Efficiency of Heat Dissipation through the Heat Sink-A Review,” (in eng), Materials (Basel), vol. 16, no. 15, Jul. 29 2023, doi: 10.3390/ma16155348.
[14] Y. H. Choong, M. Krishnan, and M. Gupta, “Recent Advances in the 3D Printing of Pure Copper Functional Structures for Thermal Management Devices,” Technologies, vol. 11, no. 5, doi: 10.3390/technologies11050141.
[15] E. C. Silva, M. Sampaio A, and A. J. Pontes, “Evaluation of Active Heat Sinks Design under Forced Convection-Effect of Geometric and Boundary Parameters,” (in eng), Materials (Basel), vol. 14, no. 8, Apr. 18 2021, doi: 10.3390/ma14082041.
[16] Y. Guo et al., “Thermal performance of a 3D printed lattice-structure heat sink packaging phase change material,” Chinese Journal of Aeronautics, vol. 34, no. 5, pp. 373-385, 2021/05/01/2021, doi: doi.org/10.1016/j.cja.2020.07.033.
[17] D. Shamvedi, O. J. McCarthy, E. O'Donoghue, C. Danilenkoff, P. O'Leary, and R. Raghavendra, “3D Metal printed heat sinks with longitudinally varying lattice structure sizes using direct metal laser sintering,” Virtual and Physical Prototyping, vol. 13, no. 4, pp. 301-310, 2018/10/02 2018, doi: 10.1080/17452759.2018.1479528.
[18] C. Zhang, Y. Li, W. Kang, X. Liu, and Q. Wang, “Current advances and future perspectives of additive manufacturing for functional polymeric materials and devices,” SusMat, vol. 1, no. 1, pp. 127-147, 2021, doi: 10.1002/sus2.11.
[19] M. Smith. “3D Printing Allows for Complex, High Surface Area Geometries Optimized for Convection Cooling.” Electronics Cooling. www.electronics-cooling.com/2019/07/3d-printing-allows-for-complex-high-surface-area-geometries-optimized-for-convection-cooling/ (accessed 2022).
[20] P. Roudný and T. Syrový, “Thermal conductive composites for FDM 3D printing: A review, opportunities and obstacles, future directions,” Journal of Manufacturing Processes, vol. 83, pp. 667-677, 2022/11/01/2022, doi:
   doi.org/10.1016/j.jmapro.2022.09.026.
[21] X. C. Tong, Advanced Materials for Thermal Management of Electronic Packaging. Springer, 2011.
[22] C.-P. Huang et al., “Crystal Transformation of Cubic BN Nanoislands to Rhombohedral BN Sheets on AlN for Deep-UV Light-Emitting Diodes,” ACS Applied Nano Materials, vol. 3, no. 6, pp. 5285-5290, 05/05 2020, doi: 10.1021/acsanm.0c00681.
[23] H. Song, J. Liu, B. Liu, J. Wu, H.-M. Cheng, and F. Kang, “Two-Dimensional Materials for Thermal Management Applications,” Joule, vol. 2, no. 3, pp. 442-463, 2018/03/21/2018, doi: doi.org/10.1016/j.joule.2018.01.006.
[24] A. Gurijala, R. B. Zando, J. L. Faust, J. R. Barber, L. Zhang, and R. M. Erb, “Castable and Printable Dielectric Composites Exhibiting High Thermal Conductivity via Percolation-Enabled Phonon Transport,” Matter, vol. 2, no. 4, pp. 1015-1024, 2020/04/01/2020, doi: doi.org/10.1016/j.matt.2020.02.001.
[25] S. Zhou et al., “Modeling the in-plane thermal conductivity of a graphite/polymer composite sheet with a very high content of natural flake graphite,” Carbon, vol. 50, no. 14, pp. 5052-5061, 2012/11/01/2012, doi: doi.org/10.1016/j.carbon.2012.06.045.
[26] K. Niendorf and B. Raeymaekers, “Additive Manufacturing of Polymer Matrix Composite Materials with Aligned or Organized Filler Material: A Review,” Advanced Engineering Materials, vol. 23, no. 4, p. 2001002, 2021, doi: 10.1 002/adem.202001002.
[27] M. Spoerk et al., “Polypropylene Filled With Glass Spheres in Extrusion-Based Additive Manufacturing: Effect of Filler Size and Printing Chamber Temperature,” Macromolecular Materials and Engineering, vol. 303, no. 7, p. 1800179, 2018/07/01 2018, doi: doi.org/10.1002/mame.201800179.
[28] J. Gonzalez-Gutierrez, S. Cano, S. Schuschnigg, C. Kukla, J. Sapkota, and C. Holzer, “Additive Manufacturing of Metallic and Ceramic Components by the Material Extrusion of Highly-Filled Polymers: A Review and Future Perspectives,” Materials, vol. 11, no. 5, doi: 10.3390/ma11050840.
[29] J. J. Fallon, S. H. McKnight, and M. J. Bortner, “Highly loaded fiber filled polymers for material extrusion: A review of current understanding,” Additive Manufacturing, vol. 30, p. 100810, 2019/12/01/2019, doi: doi.org/10.1016/j.addma.2019.100810.
[30] B. Almuallim, W. S. W. Harun, I. J. Al Rikabi, and H. A. Mohammed, “Thermally conductive polymer nanocomposites for filament-based additive manufacturing,” Journal of Materials Science, vol. 57, no. 6, pp. 3993-4019, 2022/02/01 2022, doi: 10.1007/s10853-021-06820-2.
[31] S. Singh, G. Singh, C. Prakash, and S. Ramakrishna, “Current status and future directions of fused filament fabrication,” Journal of Manufacturing Processes, vol. 55, pp. 288-306, 2020/07/01/2020, doi: doi.org/10.1016/j.jmapro.2020.04.049.
[32] S. Kumar, R. Singh, T. P. Singh, and A. Batish, “Fused filament fabrication: A comprehensive review,” Journal of Thermoplastic Composite Materials, vol. 36, no. 2, pp. 794-814, 2023/02/01 2020, doi: 10.1177/0892705720970629.
[33] J. Go, S. N. Schiffres, A. G. Stevens, and A. J. Hart, “Rate limits of additive manufacturing by fused filament fabrication and guidelines for high-throughput system design,” Additive Manufacturing, vol. 16, pp. 1-11, 2017/08/01/2017, doi: doi.org/10.1016/j.addma.2017.03.007.
[34] J. Steuben, D. L. Van Bossuyt, and C. Turner, “Design for Fused Filament Fabrication Additive Manufacturing,” 2015. [Online]. Available: doi.org/10.1115/DETC2015-46355.
[35] A. Yadav et al., “Fused filament fabrication: A state-of-the-art review of the technology, materials, properties and defects,” International Journal on Interactive Design and Manufacturing (IJIDeM), vol. 17, no. 6, pp. 2867-2889, 2023/12/01 2023, doi: 10.1007/s12008-022-01026-5.
[36] T. J. Quill et al., “Thermal and mechanical properties of 3D printed boron nitride—ABS composites,” Applied Composite Materials, vol. 25, no. 5, pp. 1205-1217, 2018, doi: 10.1007/s10443-017-9661-1.
[37] N. Sharma. “Fueling up today's electronics with the astonishing Thermal Management Solutions.” www.eletimes.com/fuelling-up-todays-electronics-with-the-astonishing-thermal-management-solutions (accessed 2022).
[38] T. Nguyen, “Thermal Conductivity of Filler and Un-filler Materials,” in 2022 IEEE Electrical Insulation Conference (EIC), 19-23 Jun. 2022 2022, pp. 419-423, doi: 10.1109/EIC51169.2022.9833203.
[39] C. P. Wong and R. S. Bollampally, “Comparative study of thermally conductive fillers for use in liquid encapsulants for electronic packaging,” IEEE Transactions on Advanced Packaging, vol. 22, no. 1, pp. 54-59, 1999, doi: 10.1109/6040.746543.
[40] K. Hart, R. Dunn, and E. Wetzel, “Increased fracture toughness of additively manufactured semi-crystalline thermoplastics via thermal annealing,” Polymer, vol. 211, p. 123091, 12/01 2020, doi: 10.1016/j.polymer.2020.123091.
[41] B. J. M. Paudel, Mohammad; Thompson, Scott M., “Multi-Objective Topology Optimization of Additively Manufactured Heat Exchangers,” presented at the Solid Freeform Fabrication Symposium—An Additive Manufacturing Conference, 2019.
[42] T. Mulholland, S. Goris, J. Boxleitner, T. A. Osswald, and N. Rudolph, “Process-Induced Fiber Orientation in Fused Filament Fabrication,” Journal of Composites Science, vol. 2, no. 3, doi: 10.3390/jcs2030045.
[43] K. Sanada, Y. Tada, and Y. Shindo, “Thermal conductivity of polymer composites with close-packed structure of nano and micro fillers,” Composites Part A: Applied Science and Manufacturing, vol. 40, no. 6, pp. 724-730, 2009/07/01/2009, doi: doi.org/10.1016/j.compositesa.2009.02.024.
[44] A. M. Peterson, “Review of acrylonitrile butadiene styrene in fused filament fabrication: A plastics engineering-focused perspective,” Additive Manufacturing, vol. 27, pp. 363-371, 2019/05/01/2019, doi: doi.org/10.1016/j.addma.2019.03.030.
[45] A. Zych et al., “Super Tough Polylactic Acid Plasticized with Epoxidized Soybean Oil Methyl Ester for Flexible Food Packaging,” ACS Applied Polymer Materials, vol. 3, no. 10, pp. 5087-5095, 2021/10/08 2021, doi: 10.1021/acsapm.1c00832.
[46] H. N. Redfearn and J. M. Goddard, “Reactive Extrusion of Poly(lactic acid)-graft-Curcumin Antioxidant and Intelligent Packaging,” ACS Applied Polymer Materials, 2023/12/05 2023, doi: 10.1021/acsapm.3c01820.
[47] D. Kong et al., “Functionalized Boron Nitride Nanosheets/Poly(I-lactide) Nanocomposites and Their Crystallization Behavior,” Polymers, vol. 11, no. 3, p. 440, 2019, doi: 10.3390/polym11030440.
[48] L. Bai, X. Zhao, R.-Y. Bao, Z.-Y. Liu, M.-B. Yang, and W. Yang, “Effect of temperature, crystallinity and molecular chain orientation on the thermal conductivity of polymers: a case study of PLLA,” Journal of Materials Science, vol. 53, no. 14, pp. 10543-10553, 2018/07/01 2018, doi: 10.1007/s10853-018-2306-4.
[49] L. Mu et al., “Molecular Origin of Efficient Phonon Transfer in Modulated Polymer Blends: Effect of Hydrogen Bonding on Polymer Coil Size and Assembled Microstructure,” The Journal of Physical Chemistry C, vol. 121, no. 26, pp. 14204-14212, 2017/07/06 2017, doi: 10.1021/acs.jpcc.7b03726.
[50] B. A. A. M. M. S. J. Z. J. Matisons. Silane Coupling Agents: Connecting Across Boundaries. (2014). [Online]. Available: www.gelest.com/themencode-pdf-viewer/?file=https://www.gelest.com/wp-content/uploads/Goods-PDF-brochures-couplingagents.pdf
[51] J. L. Olmedo-Martinez et al., “Ternary Poly(ethylene oxide)/Poly(L,L-lactide) PEO/PLA Blends as High-Temperature Solid Polymer Electrolytes for Lithium Batteries,” ACS Applied Polymer Materials, vol. 3, no. 12, pp. 6326-6337, 2021, doi: 10.1021/acsapm.1c01093.

What is claimed is:

1. A thermally conductive polymer composite (TCPC) material comprising
(i) a semi-crystalline polymeric material; and
(ii) a plurality of thermally conductive particles embedded in the polymeric material;
wherein the TCPC material comprises crystallites of the polymer material that form connections between the thermally conductive particles, or wherein the TCPC material has a thermal conductivity of at least 15 W/m·K.

2. The TCPC material of claim 1, wherein the plurality of thermally conductive particles comprise hexagonal boron nitride (hBN) platelets.

3. The TCPC material of claim 2, wherein the hBN platelets comprise hBN platelets having a size in a nanometer range and hBN platelets having a size in a micrometer range.

4. The TCPC material of claim 3, wherein the hBN platelets are present in a concentration range of 1 to 10 vol % in the nanometer range and 30 to 60 vol % in the micrometer range.

5. The TCPC material of claim 1, wherein at least 50% of the thermally conductive particles are in contact with one or more of said crystallites.

6. The TCPC material of claim 1, wherein the thermally conductive particles have a planar structure and are predominantly aligned in the TCPC material with the planar structures in a parallel configuration.

7. The TCPC material of claim 1, wherein the polymeric material is a thermoplastic material containing crystallites.

8. The TCPC material of claim 1, wherein the thermally conductive particles have been surface treated using a method selected from the group consisting of plasma treatment, solvent etching, metallization via evaporation, metallization via sputtering, UV-ozone, diamond coating, diamond-like coating, graphene coating, and graphitic coating.

9. The TCPC material of claim 1, wherein the polymer material comprises at least 10% or at least 30% volume fraction in form of crystallites.

10. The TCPC material of claim 1, wherein the polymer material comprises one or more of polyethylene (PE), low density PE (LDPE), high density PE (HDPE), ultra high molecular weight PE (UHMW PE), polyamide (PA), poly-para-phenylene terephthalamide (Kevlar), poly(meta phenyleneisophthalamide), polyetheretherketone (PEEK), polyoxymethylene, polyethylene terephthalate (PET), polybutylene terephthalate (PBT), polytetrafluoroethylene (PTFE), polypropylene (PP), isotactic PP, syndiotactic polystyrene (PS), polyphenylene sulfide (PPS), fluorinated ethylene propylene (FEP), polyvinylidene fluoride (PVDF), polylactic acid (PLA), and acrylonitrile butadiene styrene (ABS).

11. The TCPC material of claim 1, wherein the plurality of thermally conductive particles comprises particles having chemically derivatized surfaces.

12. The TCPC material of claim 11, wherein the chemical derivatization comprises hydroxylation or silanization of the particles.

13. The TCPC material of claim 1, wherein the TCPC material is electrically insulating and transparent to radio frequency electromagnetic radiation.

14. The TCPC material of claim 1, wherein the TCPC material is configured as a filament suitable for use in a fused filament fabrication (FFF) process.

15. The TCPC material of claim 14, wherein the filament has a resilience of at least about 0.2 J/m³ and can be wrapped tightly around a spool of diameter 200 mm or less without filament breakage.

16. A thermal management structure for an electronic device, the thermal management structure comprising the TCPC material according to claim 1.

17. The thermal management structure of claim 16, wherein the structure is made by a process comprising 3D printing, injection molding, compression molding, or machining.

18. An electronic device comprising the TCPC material of claim 1.

19. A method of making a TCPC material, the method comprising
(a) providing a polymer material and a plurality of thermally conductive particles;
(b) heating the polymer material to prepare a polymer melt;
(c) mixing the plurality of thermally conductive particles with the polymer melt; and
(d) forming the mixture from (c) into a desired shape and allowing the formed mixture to cool to form the TCPC material.

20. The method of claim 19, further comprising
(e1) annealing the TCPC material by heating the material to a temperature below a melting temperature of the TCPC material for a period of time, whereby one or more properties of the material are altered.

21. The method of claim 19, further comprising
(e2) slow-cooling the TCPC from a temperature above Tc and Tg and below Tm down to about ambient temperature, whereby crystallite growth within the TCPC is promoted.

22. The method of claim 19, wherein one or more process additives are added to the mixture formed in step (c), wherein the process additives are selected from the group consisting of solvents, plasticizers, surfactants, dispensing aids, antioxidants, stabilizers, and colorants.

23. The method of claim 19, wherein any of steps (b)-(d) is performed using an extruder device.

24. The method of claim 19, wherein the thermally conductive particles are hBN platelets, wherein the polymer material comprises one or more of polyethylene (PE), low density PE (LDPE), high density PE (HDPE), ultra high molecular weight PE (UHMW PE), polyamide (PA), poly-para-phenylene terephthalamide (Kevlar), poly(meta phenyleneisophthalamide), polyetheretherketone (PEEK), polyoxymethylene, polyethylene terephthalate (PET), polybutylene terephthalate (PBT), polytetrafluoroethylene (PTFE), polypropylene (PP), isotactic PP, syndiotactic polystyrene (PS), polyphenylene sulfide (PPS), fluorinated ethylene propylene (FEP), polyvinylidene fluoride (PVDF), polylactic acid (PLA), and acrylonitrile butadiene styrene (ABS), and wherein the hBN platelets comprise hBN platelets having a size in a nanometer range and hBN platelets having a size in a micrometer range.

25. A method of making a thermal dissipation structure, the method comprising forming the TCPC material of claim 1 into a structure for use as a thermal dissipation structure.

26. The method of claim 25, wherein the thermal dissipation structure serves as, or is incorporated into, a device selected from the group consisting of a thermal management device, a heat sink or a heat spreader, a heat exchanger, a radiator, a cold plate, a low-loss dielectric RF component, a power inverter, a solar cell, a neutron shield, an encapsulant, an antenna, or a medical device.

27. A TCPC material made by the method of claim 19.

28. A method of designing or optimizing a process for producing a TCPC material suitable for use as a filament in a fused filament fabrication (FFF) process, the method comprising the steps of
(a) selecting a polymer material having a melting point and a viscosity suitable for said FFF process;
(b) selecting one or more thermally conductive particles for use as inclusions in the polymer material, wherein the one or more particle materials have a particle size distribution comprising particles having a size in a nanometer range and particles having a size in a micrometer range;
(c) extruding a mixture of the polymer material of (a) and the thermally conductive particles of (b) to form a filament of a candidate TCPC material;
(d) analyzing the filament according to one or more parameters selected from melting temperature of the filament, viscosity of a melt of the filament, suitability of the filament for use in an FFF process, thermal conductivity of the filament, dielectric properties of the filament, resilience of the filament, and spoolability of the filament;
(e) based on the analyzing of (d), revising the polymer material selection of (a) and/or the thermally conductive particle selection of (b) and repeating steps (c) and (d) with the revised selection(s) until one or more of said parameters is within a desired range for the TCPC material.

29. A three dimensional object resulting from the deposition of a heated filament, the filament comprising the TCPC material of claim 1.

30. A three-dimensional printing process comprising the steps of
(a) heating a filament comprising the TCPC material of claim 1;
(b) extruding the filament from a nozzle;
(c) depositing the extruded filament to form a three-dimensional body, wherein the body has a geometry that is substantially identical to a digital design file that is used to program the three dimensional printing process.
